(19) United States
(12) Patent Application Publication
(10) Pub. No.: US 2025/0224166 A1
(43) Pub. Date: Jul. 10, 2025

(54) REFRIGERATOR INCLUDING THERMOELECTRIC MODULE AND METHOD OF CONTROLLING THERMOELECTRIC MODULE BY REFRIGERATOR

(71) Applicant: SAMSUNG ELECTRONICS CO., LTD., Suwon-si (KR)

(72) Inventors: Kitae PARK, Suwon-si (KR); Minjeong CHOI, Suwon-si (KR); Heejung YOUN, Suwon-si (KR)

(21) Appl. No.: 18/826,206

(22) Filed: Sep. 6, 2024

Related U.S. Application Data
(63) Continuation of application No. PCT/KR2024/096126, filed on Aug. 29, 2024.

(30) Foreign Application Priority Data
Jan. 5, 2024 (KR) 10-2024-0002443
Apr. 1, 2024 (KR) 10-2024-0044330

(51) Int. Cl. F25B 49/02; F25B 21/02

(52) U.S. Cl. CPC F25B 49/02; F25B 21/02; F25B 2600/00

(57) ABSTRACT

A refrigerator includes a main body including at least one storage chamber, doors provided to open or close the at least one storage chamber, a thermoelectric module for cooling down the at least one storage chamber, and at least one processor configured to control the thermoelectric module, where the thermoelectric module includes internal elements classified into a plurality of groups, the internal elements in each of the plurality of groups are connected to each other in series, and the plurality of groups are connected in parallel with each other to a power line connected to the thermoelectric module.

### CROSS-REFERENCE TO RELATED APPLICATION(S)

This application is a continuation application, claiming priority under § 365 (c), of International Application No. PCT/KR2024/096126, filed on Aug. 29, 2024, which is based on and claims the benefit of Korean Provisional Application No. 10-2024-0002443 filed on Jan. 5, 2024 and Korean Patent Application No. 10-2024-0044330 filed on Apr. 1, 2024, the disclosures of which are incorporated by reference herein in their entireties.

### BACKGROUND

### (1) Field

An embodiment of the disclosure relates to a refrigerator including a thermoelectric module (Peltier module) and a method of controlling a thermoelectric module by a refrigerator.

### (2) Description of the Related Art

A refrigerator is an apparatus for storing food for a long period of time without spoilage and preserves food by using freezing or refrigeration methods. A refrigerator basically uses a refrigerant to generate a cooling environment and maintain an internal temperature in the cooling environment at a set temperature.

Recently, increased amount of food is stored in a storage space of a refrigerator. Accordingly, techniques for effectively managing the temperature of the storage space have been researched.

### SUMMARY

An embodiment of the disclosure provides a refrigerator including a thermoelectric module (Peltier module) on an upper end of a main body. The thermoelectric module includes internal elements classified or divided into a plurality of groups connected in parallel with each other to a power line connected to the thermoelectric module, and thus, loss of performance of the entire thermoelectric module due to one defective internal element may be effectively prevented.

A refrigerator according to an embodiment of the disclosure may include a main body including at least one storage chamber, doors provided to open or close the at least one storage chamber, a thermoelectric module configured to cool down the at least one storage chamber, and at least one processor configured to control the thermoelectric module. A thermoelectric module according to an embodiment of the disclosure includes internal elements classified into a plurality of groups, where the internal elements in each of the plurality of groups are connected to each other in series. The plurality of groups is connected in parallel with each other to a power line connected to the thermoelectric module.

### BRIEF DESCRIPTION OF THE DRAWINGS

FIG. 1 is a diagram illustrating a refrigerator including a thermoelectric module according to an embodiment of the disclosure.

FIG. 2 is a diagram showing an upper portion of a storage chamber in a refrigerator including a thermoelectric cooling device according to an embodiment of the disclosure.

FIG. 3 is an exploded view of a thermoelectric cooling device including a thermoelectric module according to an embodiment of the disclosure.

FIG. 4 is a diagram illustrating a freezing cycle device according to an embodiment of the disclosure.

FIG. 5A is a diagram illustrating a thermoelectric module with internal elements classified in two groups, according to an embodiment of the disclosure.

FIG. 5B is a diagram describing functions of a thermoelectric module with internal elements classified in two groups, according to an embodiment of the disclosure.

FIG. 6A is a diagram illustrating a thermoelectric module with internal elements classified in three groups, according to an embodiment of the disclosure.

FIG. 6B is a diagram describing functions of a thermoelectric module with internal elements classified in three groups, according to an embodiment of the disclosure.

FIG. 7 is a table for describing changes in a voltage and resistance when internal elements of a thermoelectric module according to an embodiment of the disclosure are grouped into a plurality of groups.

FIG. 8 is a diagram for describing an arrangement of internal elements included in a thermoelectric module according to an embodiment of the disclosure.

FIG. 9A is a block diagram of a thermoelectric module according to an embodiment of the disclosure.

FIG. 9B is a diagram for describing a substrate pattern in a thermoelectric module according to an embodiment of the disclosure.

FIG. 9C is a diagram for describing a pattern during substrate coupling in a thermoelectric module according to an embodiment of the disclosure.

FIG. 10 is a flowchart of a method, performed by a refrigerator, of controlling a thermoelectric module, according to an embodiment of the disclosure.

FIG. 11 is a diagram for describing operations of a refrigerator for controlling a thermoelectric module by using a voltage sensing circuit and a current sensing circuit, according to an embodiment of the disclosure.

FIG. 12 is a flowchart of a method of a refrigerator to output a notification indicating that a thermoelectric module requires checking, according to an embodiment of the disclosure.

FIG. 13 is a diagram describing an operation of a refrigerator to output a notification indicating that a thermoelectric module requires checking, according to an embodiment of the disclosure.

FIG. 14 is a block diagram for describing functional elements of a refrigerator according to an embodiment of the disclosure.

FIG. 15 is a diagram for describing a communication system in a refrigerator according to an embodiment of the disclosure.

FIG. 16 is a diagram for describing an operation of a refrigerator linking with a user terminal, according to an embodiment of the disclosure.

FIG. 17 is a flowchart of a method, performed by a refrigerator, of determining a notification type or a device to output a notification according to the number of groups that lost functions, from among a plurality of groups, according to an embodiment of the disclosure.

FIG. 18 is a diagram for describing an operation of a refrigerator to determine a notification type or a device to output a notification according to the number of groups that lost functions, according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

All terms including descriptive or technical terms which are used herein should be construed as having meanings that are obvious to one of ordinary skill in the art. However, the terms may have different meanings according to an intention of one of ordinary skill in the art, precedent cases, or the appearance of new technologies. Also, some terms may be arbitrarily selected by the applicant. In this case, the meaning of the selected terms will be described in the detailed description of an embodiment of the disclosure. Thus, the terms used herein have to be defined based on the meaning of the terms together with the description throughout the specification.

Throughout the disclosure, the expression “at least one of a, b or c” or “at least one selected from a, b or c” indicates only a, only b, only c, both a and b, both a and c, both b and c, all of a, b, and c, or variations thereof.

It will be further understood that the terms “comprises” and/or “comprising,” when used in this specification, specify the presence of stated components, but do not preclude the presence or addition of one or more components. In addition, the terms such as “ . . . unit”, “module”, etc. provided herein indicate a unit performing at least one function or operation, and may be realized by hardware, software, or a combination of hardware and software.

It is known to those skilled in the art that blocks of a flowchart and a combination of flowcharts may be represented and executed by one or more computer programs including computer executable instructions. One or more computer programs may be stored in a single memory or separately stored in a plurality of different memories.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

All functions or operations described in the specification may be processed by one processor or a combination of processors. One processor or a combination of processors may include a circuitry such as application processor (AP), a communication processor (CP), a graphic processing unit (GPU), a neural processing unit (NPU), a microprocessor unit (MPU), a system on chip (SoC), an integrated chip (IC), etc., as a circuitry performing processing.

Hereinafter, one or more embodiments of the disclosure will be described in detail with reference to accompanying drawings to the extent that one of ordinary skill in the art would be able to carry out the disclosure. However, an embodiment of the disclosure may be implemented in various manners, and is not limited to one or more embodiments of the disclosure described herein. In addition, components irrelevant with the description are omitted in the drawings for clear description of an embodiment of the disclosure, and like reference numerals are used for similar components throughout the entire specification of the disclosure.

A refrigerator according to an embodiment of the disclosure may include a main body.

“Main body” may include an inner case, an outer case arranged outside the inner case, and an insulating material provided between the inner case and the outer case.

“Inner case” may include at least one of a case, a plate, a panel, or a liner forming a storage chamber. The inner case may be formed as one body or may be formed by assembling a plurality of plates. “Outer case” may form the exterior of the main body and may be coupled to the outer side of the inner case so that the insulating material can be disposed between the inner case and the outer case.

“Insulating material” may insulate interior and exterior of the storage chamber so that a temperature in the storage chamber may be maintained at a set appropriate temperature without being affected by an external environment of the storage chamber. According to an embodiment of the disclosure, the insulating material may include a foam insulating material. Urethane foam in which polyurethane and foaming agent are mixed is injected and foamed between the inner case and the outer case, and thus, the foam insulating material may be formed.

According to an embodiment of the disclosure, the insulating material may include a vacuum insulating material in addition to the foam insulating material, or the insulating material may be only formed of the vacuum insulating material, instead of the foam insulating material. The vacuum insulating material may include a core material, and an outer cover material accommodating the core material and sealing the inside to vacuum state or a pressure close to the vacuum. However, the insulating material is not limited to the foam insulating material or vacuum insulating material, but may include various materials that may be used for insulation.

“Storage chamber” may include a space defined by the inner case. The storage chamber may further include an inner case defining a space corresponding to the storage chamber. The storage chamber may store various items such as food, medicine, cosmetics, etc., and the storage chamber may be formed to have at least one open side in order to withdraw or accommodate items.

The refrigerator may include one or more storage chambers. When two or more storage chambers are formed in the refrigerator, the storage chambers may have different purposes and may be maintained at different temperatures from each other. To this end, the storage chambers may be partitioned by partition walls including the insulating material.

The storage chamber may be provided to be maintained at an appropriate temperature range according to the purpose thereof, and may include a “refrigerating chamber”, a “freezing chamber”, or a “temperature changeable chamber” which are distinguished according to the use and/or the temperature range. The refrigerating chamber may be maintained at a temperature that is appropriate for refrigerating items, and the freezing chamber may be maintained at a temperature appropriate for freezing the items. “Refrigerating” may denote cooling-down the items within a non-freezing range, for example, the refrigerating chamber may be maintained within a range of 0° Celsius to 7° Celsius. “Freezing” may denote freezing the items or cooling down the items to be stored in a frozen state, for example, the freezing chamber may be maintained within a range of −20° Celsius to −1° Celsius. The temperature changeable chamber may be used as one of the refrigerating chamber or the freezing chamber according to a selection of a user or regardless of the selection of the user.

The storage chamber may be referred to by various names such as “vegetable chamber”, “fresh chamber”, “cooling chamber”, “ice-making chamber”, etc. in addition to the “refrigerating chamber”, “freezing chamber”, and “temperature changeable chamber”. In addition, terms such as “refrigerating chamber”, “freezing chamber”, and “temperature changeable chamber” used herein should be appreciated to encompass the storage chamber having corresponding purpose and temperature range.

According to an embodiment of the disclosure, the refrigerator may include at least one door configured to open or close open one side of the storage chamber. The door may be provided to open or close each of one or more storage chambers, or one door may be provided to open or close a plurality of storage chambers. The door may be installed on the front surface of the main body to be rotatable or slidable.

“Door” may be configured to seal the storage chamber when the door is closed. The door may include the insulating material, like the main body, in order to insulate the storage chamber when the door is closed.

According to an embodiment of the disclosure, the door may include an outer door plate forming the front surface of the door, an inner door plate forming the rear surface of the door and facing the storage chamber, an upper cap, a lower cap, and a door insulator provided in the upper cap and the lower cap.

A gasket that seals the storage chamber by coming into close contact with the front surface of the main body may be provided at the boundary of the inner door plate. The inner door plate may include a dyke protruding backward so that door baskets for storing items may be attached.

According to an embodiment of the disclosure, the door may include a door body, and a front panel which is separately coupled to the front side of the door body and forms the front surface of the door. The door body may include the outer door plate forming the front surface of the door body, the inner door plate forming the rear surface of the door body and facing the storage chamber, the upper cap, the lower cap, and the door insulator provided inside the upper cap and the lower cap.

The refrigerator may be classified in a French door type, a side-by-side type, a bottom mounted freezer (BMF), a top mounted freezer (TMF), or a one-door refrigerator according to the arrangement of the door and the storage chamber.

According to an embodiment of the disclosure, the refrigerator may include a cold air supply apparatus provided to supply cold air to the storage chamber.

“Cold air supply apparatus” may include machines, mechanisms, electronic devices, and/or systems combining the same, capable of generating cold air and guiding the cold air to cool down the storage chamber.

According to an embodiment of the disclosure, the cold air supply apparatus may generate the cold air through freezing cycle including compressing, condensing, expanding, and vaporizing of a refrigerant. To this end, the cold air supply apparatus may include a freezing cycle apparatus having a compressor, a condenser, an expanding device (expander), and a vaporizer capable of driving the freezing cycle. According to an embodiment of the disclosure, the cold air supply apparatus may include a semiconductor such as a thermoelectric element. The thermoelectric element may cool down the storage chamber through heating and cooling operations by Peltier effect.

According to an embodiment of the disclosure, the refrigerator may include a machinery chamber provided so that at least some components of the cold air supply apparatus may be arranged.

“Machinery chamber” may be provided to be partitioned and insulated from the storage chamber in order to prevent the heat generated from the components arranged in the machinery chamber from transferring to the storage chamber. The interior of the machinery chamber may be formed to communicate with the outside of the main body so as to dissipate heat from the components arranged in the machinery chamber.

According to an embodiment of the disclosure, the refrigerator may include a dispenser provided in the door for providing water and/or ice. The dispenser may be provided in the door so that a user may access without opening the door.

According to an embodiment of the disclosure, the refrigerator may include an ice-making apparatus provided to generate ice. The ice-making apparatus may include an ice-making tray storing water, an ice-separating device for separating ice from the ice-making tray, and an ice bucket storing ice generated by the ice-making tray.

According to an embodiment of the disclosure, the refrigerator may include a controller for controlling the refrigerator.

“Controller” may include memory for storing or recording programs and/or data for controlling the refrigerator, and a processor that outputs a control signal for controlling the cold air supply apparatus, etc. according to the programs and/or data stored in the memory.

The memory may store or record various information, data, instructions, programs, etc. required to operate the refrigerator. The memory may record temporary data generated while generating a control signal for controlling components included in the refrigerator. The memory may include at least one of a volatile memory or a non-volatile memory, or a combination thereof.

The processor controls overall operations of the refrigerator. The processor may control the components of the refrigerator by executing the programs stored in the memory. The processor may include an additional NPU performing operations of an artificial intelligence (AI) model. Also, the processor may include a central processor unit (CPU), a graphics processor unit (GPU), etc. The processor may generate a control signal for controlling operations of the cold air supply apparatus. For example, the processor may receive temperature information of the storage chamber from a temperature sensor and may generate a cooling control signal for controlling operations of the cold air supply apparatus based on the temperature information of the storage chamber.

Also, the processor may process user inputs from a user interface according to the programs and/or data recorded/stored in the memory and control the operations of the user interface. The user interface may be provided via an input interface and an output interface. The processor may receive the user input from the user interface. Also, the processor may transfer a display control signal and image data for displaying images on the user interface to the user interface, in response to the user input.

The processor and the memory may be integrally or separately provided. The processor may include one or more processors. For example, the processor may include a main processor and at least one sub-processor. The memory may include one or more memories.

The processor may include various processing circuits and/or a plurality of processors. For example, the term “processor” used throughout the disclosure including claims may include various processing circuits including at least one processor. In at least one processor, one or more processors may be configured to perform various functions described in the disclosure, individually and/or collectively in a distributed manner. Without the limitation of terms such as “processor”, “at least one processor”, and “one or more processors”, a situation in which one processor performs some of the functions and another processor(s) performs some of the other, and a single processor may perform all of the functions, may be covered. Also, at least one processor may include combinations of processors performing various functions disclosed in a distributed manner. At least one processor may execute program instructions in order to achieve or execute various functions.

According to an embodiment of the disclosure, the refrigerator may include the processor and the memory controlling all components included in the refrigerator, and may include a plurality of processor and a plurality of memories individually controlling components of the refrigerator. For example, the refrigerator may include a processor and a memory controlling operations of the cold air supply apparatus according to an output from the temperature sensor. Also, the refrigerator may separately include a processor and a memory controlling operations of the user interface according to the user input.

A communication module (communication interface) may communicate with an external device such as a server, a mobile device, another home appliance, etc. through a peripheral access point (AP). The AP may connect a local area network (LAN) to which the refrigerator or user device is connected to a wide area network (WAN) to which the server is connected. The refrigerator or the user device may be connected to the server through the wide area network (WAN).

The input interface may include a key, a touch screen, a microphone, etc. The input interface may receive the user input and transfer the user input to the processor.

The output interface may include a display unit, a speaker, etc. The output interface may output various notifications, messages, information, etc. generated in the processor.

Hereinafter, a refrigerator according to various embodiments will be described in detail with reference to the accompanying drawings.

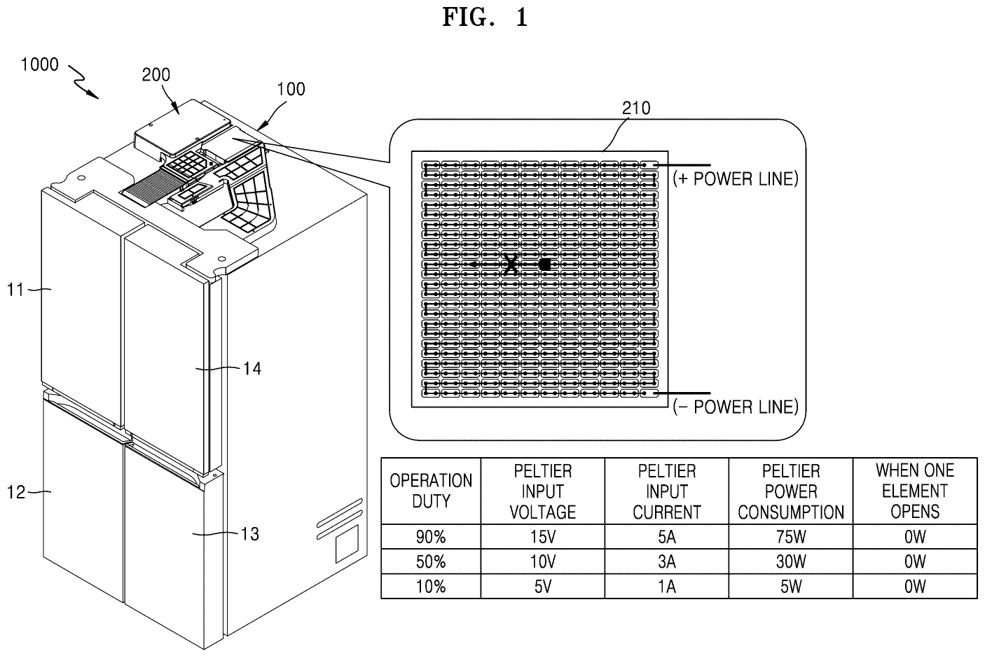

FIG. 1 is a diagram illustrating a refrigerator 1000 including a thermoelectric module 210 according to an embodiment of the disclosure.

The refrigerator 1000 according to an embodiment of the disclosure may be an electronic device (or home appliance) for refrigerating or freezing object, e.g., food, stored therein. The refrigerator 1000 may store medicine, alcoholic liquor, cosmetics, etc. as well as food.

The refrigerator 1000 according to an embodiment of the disclosure may include, but is not limited to, a main body 100 including at least one storage chamber configured to store items (e.g., food, medicine, alcoholic liquor, cosmetics, etc.), at least one door (e.g., 11, 12, 13, and 14) provided to open or close the at least one storage chamber, and a thermoelectric cooling device 200 configured to cool down the at least one storage chamber.

According to an embodiment of the disclosure, the main body 100 of the refrigerator 1000 may include an upper surface, a lower surface, a left surface, a right surface, and a rear surface, and the at least one door (e.g., 11, 12, 13, and 14) may be arranged on a front surface. In an embodiment, as shown in FIG. 1, the refrigerator 1000 includes four doors 11, 12, 13, and 14 as an example, but is not limited thereto. In an embodiment, the refrigerator 1000 may include one, two, three, five, or more doors.

According to an embodiment of the disclosure, the thermoelectric cooling device 200 may be provided on an upper end (upper wall) of the main body 100. For example, the thermoelectric cooling device 200 may be provided on the upper side of the upper storage chamber to cool down the upper storage chamber. However, the disclosure is not limited thereto, and the thermoelectric cooling device 200 may be provided on the rear end (rear wall) of the main body 100.

The thermoelectric cooling device may include a thermoelectric module 210. The thermoelectric module 210 may be a semiconductor device configured to convert electrical energy into thermal energy by using Peltier effect, and may be referred to as a thermoelectric semiconductor device, a thermoelectric element module, a Peltier element, a Peltier module, etc. The Peltier effect may denote a phenomenon in which, when direct current (DC) voltage is applied to opposite ends of two different elements (e.g., N-type semiconductor and a P-type semiconductor), a heat adsorption reaction occurs on one surface and a heat generation reaction occurs on the other according to the direction of the current.

The thermoelectric module 210 may include a heating portion and a cooling portion. When the power is applied to the thermoelectric module 210, heat generation may occur in the heating portion and heat adsorption may occur in the cooling portion. The thermoelectric module 210 may have a thin hexahedral shape, and the heating portion may be provided on one surface of the thermoelectric module 210 and the cooling portion may be provided on an opposite surface, which is opposite to the one surface.

In an embodiment, the thermoelectric module 210 may have P-type elements and N-type elements that are alternately mounted between ceramic printed circuit boards (PCBs) located on upper and lower portions thereof. Here, the P-type elements and the N-type elements mounted between the ceramic PCBs may be connected in series according to the order. However, when hundreds of P-type elements and N-type elements are connected in series, the entire performance of the thermoelectric module 210 may be lost even when there is a defect in only one element. For example, when an open defect occurs in one element of the thermoelectric module 210, a power consumption of the thermoelectric module 210 may be zero (0) watt (W). Hereinafter, the open defect denotes that one of the P-type elements or N-type elements is damaged and the circuit is open. When the entire function of the thermoelectric module 210 is lost, the temperature in the storage chamber may not be properly maintained and food stored in the storage chamber may be spoiled.

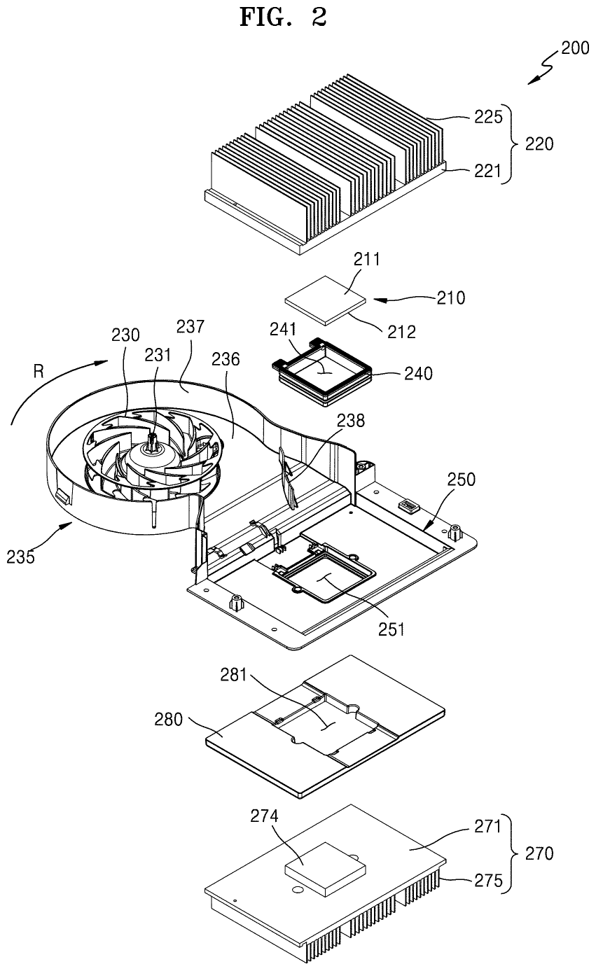

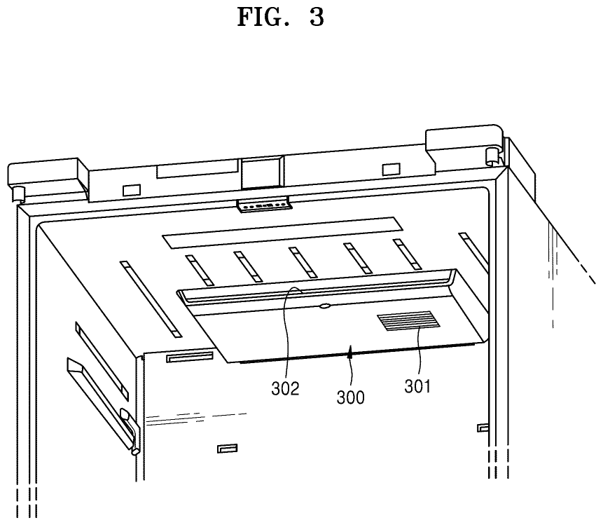

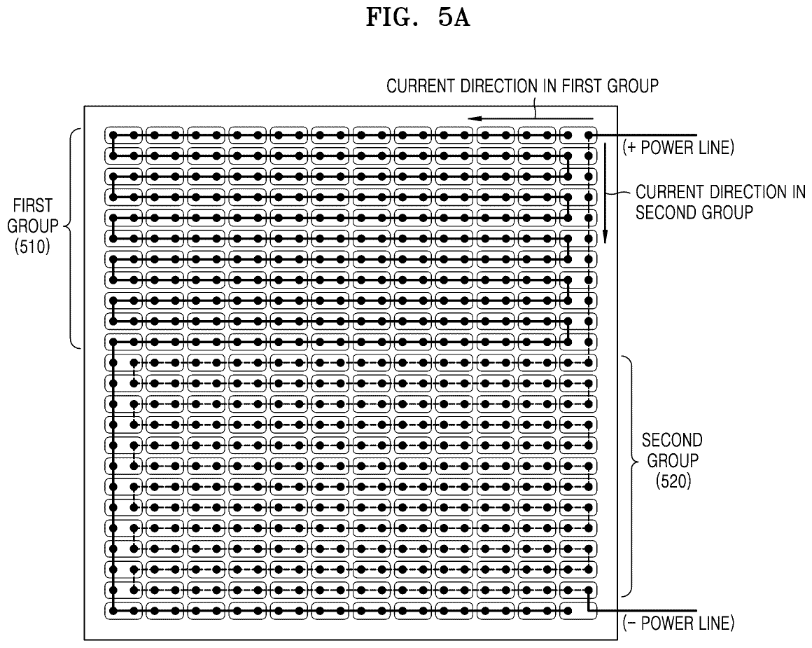

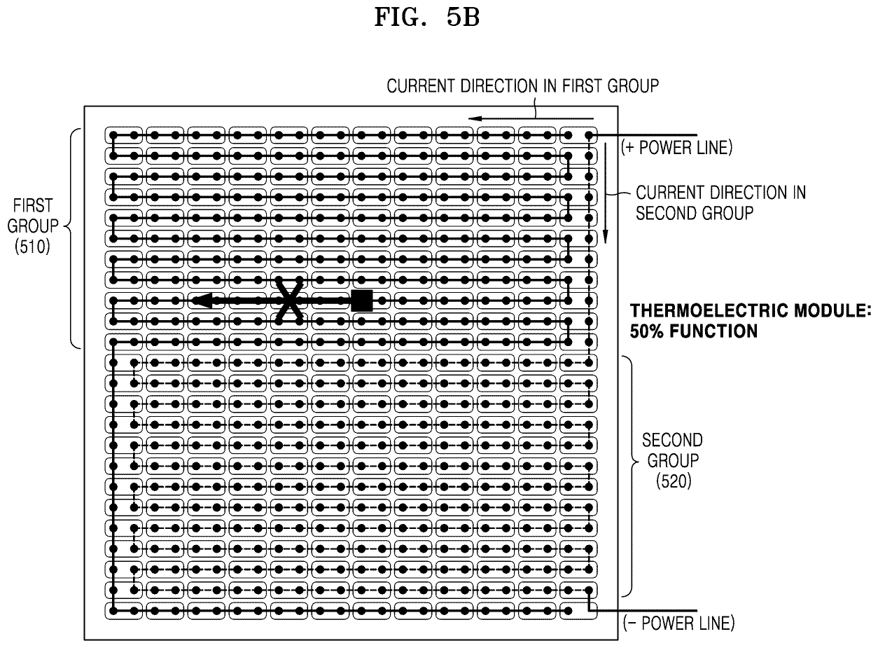

According to an embodiment of the disclosure, the internal elements included in the thermoelectric module 210 may be configured as a plurality of groups such that at least 50% of the entire performance of the thermoelectric module 210 may be maintained even when the open defect occurs in one element. Here, the plurality of groups may be connected in parallel with each other between a positive (+) power line and a negative (−) power line. An embodiment in which the internal elements included in the thermoelectric module 210 are configured in a plurality of groups will be described later with reference to FIGS. 5A to 8, and hereinafter, the thermoelectric cooling device 200 will be described in further detail with reference to FIGS. 2 and 3.

FIG. 2 is an exploded view of the thermoelectric cooling device 200 including the thermoelectric module 210 according to an embodiment of the disclosure.

In an embodiment, the thermoelectric module 210 may be located in the thermoelectric cooling device 200. The thermoelectric module 210 may include a heating portion 211 and a cooling portion 212. The thermoelectric module 210 may be provided in a way such that the heating portion 211 faces the outside of the refrigerator 100 and the cooling portion 212 faces the inside of the refrigerator 1000. For example, the thermoelectric module 210 may be provided in a way such that the heating portion 211 faces above the thermoelectric module 210 and the cooling portion 212 faces downward the thermoelectric module 210. In this case, the heating portion 211 of the thermoelectric module 210 faces the outside of the main body 100 and the cooling portion 212 of the thermoelectric module 210 may face the inside of the storage chamber. Therefore, air that exchanges heat with the heating portion 211 of the thermoelectric module 210 and becomes warm is discharged to the outside of the main body 100, and air that exchanges heat with the cooling portion 212 of the thermoelectric module 210 and becomes cool may be supplied to the storage chamber.

The thermoelectric module 210 may be disposed in a module plate 250. For example, the module plate 250 may be provided with a module plate opening 251 and the thermoelectric module 210 may be disposed inside the module plate opening 251. A length of the module plate opening 251 in the vertical direction may be greater than that of the thermoelectric module 210 in the vertical direction, and the thermoelectric module 210 may be disposed at the upper end side of the module plate opening 251. The thermoelectric cooling device 200 may include an element insulation material 240 that insulates the module plate 250 and the thermoelectric module 210 from each other. The element insulation material 240 may be disposed in the module plate opening 251 in a way such that the side surface of the thermoelectric module 210 may not come into contact with the module plate 250. The element insulation material 240 may be provided with an element insulation material opening 241 and the thermoelectric module 210 may be accommodated in the element insulation material opening 241.

The thermoelectric cooling device 200 may include a heat dissipation sink 220 that comes into contact (or is in contact) with the heating portion 211 such that the heat exchange between the heating portion 211 of the thermoelectric module 210 and the air outside the main body 100 may be performed effectively. The heat dissipation sink 220 may be located outside the main body 100. The heat dissipation sink 220 may come into contact with the heating portion 211 to absorb heat from the heating portion 211 and discharge the heat to the outside of the main body 100. The heat dissipation sink 220 may be referred to as a hot sink, a heat-dissipation heat sink, a hot heat sink, etc. The heat dissipation sink 220 may include or be formed of a metal material having high thermal conductivity. For example, the heat dissipation sink 220 may include or be formed of aluminum or copper. The heat dissipation sink 220 may include a heat dissipation sink base 221 in contact with the heating portion 211, and a plurality of heat dissipation fins 225 protruding from the heat dissipation sink base to expand a heat-transfer area. The plurality of heat dissipation fins 225 may protrude upward from the heat dissipation sink base 221.

The thermoelectric cooling device 200 may include a cooling sink 270 coming into contact with the cooling portion 212 such that the heat exchange between the cooling portion 212 and the air in the storage chamber may be performed effectively.

The cooling sink 270 may be located in the storage chamber. The cooling sink 270 may cool down the storage chamber by taking away the heat from the storage chamber and transferring the heat to the cooling portion 212. The cooling sink 270 may be referred to as a cold sink, a cooling sink, a cooling heat sink, a cold heat sink, a cooling heat sink, etc. The cooling sink 270 may including be formed of a metal material having high heat conductivity. For example, the cooling sink 270 may include or be formed of aluminum or copper. The cooling sink 270 may include a cooling sink base 271 in contact with the cooling portion 212, and a plurality of cooling fins 275 protruding from the cooling sink base 271 to expand the heat transfer area. The plurality of cooling fins 275 may protrude downward from the cooling sink base 271. The cooling sink base 271 and the plurality of cooling fins 275 may be integrally formed with each other as a single unitary indivisible part. The cooling sink 270 may include a cooling conduction portion 274 that protrudes from the cooling sink base 271 for coming into contact with the cooling portion 212 of the thermoelectric module 210.

The thermoelectric cooling device 200 may include a heat dissipation fan 230 that flows the air in a way such that heat exchange between the heat dissipation sink 220 and the outside of the main body 100 may be effectively performed.

The heat dissipation fan 230 may blow the air toward the heat dissipation sink 220. The heat dissipation fan 230 may be provided in the horizontal direction from the heat dissipation sink 220. The heat dissipation fan 230 may be provided on an outer portion of the main body 100. For example, the heat dissipation fan 230 may be provided on the upper wall.

The heat dissipation fan 230 may be a centrifugal fan that sucks in the air in an axial direction and discharges the air in a radial direction. The centrifugal fan may include a blower fan. A rotary shaft 231 of the heat dissipation fan 230 may be arranged perpendicular to the upper surface of the main body 100.

The thermoelectric cooling device 200 may include a fan case 235 that guides the air blown by the heat dissipation fan 230. The fan case 235 may include a case bottom 236 on which the heat dissipation fan 230 is installed to be rotatable, and a case scroll portion 237 that extends upward from the edge of the case bottom 236 to guide the air blown from the heat dissipation fan 230 toward the heat dissipation sink 220. The rotary shaft 231 of the heat dissipation fan 230 may be installed on the case bottom 236 to be perpendicular to the case bottom 236.

The fan case 235 may include a case guide 238 that is provided to guide the air flowing around the downstream side end portion of the case scroll portion 237 from the heat dissipation fan 230.

In an embodiment, the thermoelectric cooling device 200 may include a sink insulation material 280 that is provided between the module plate 250 and the cooling sink 270. The sink insulation material 280 may effectively prevent the heat from transferring between the heat dissipation sink 220 and the cooling sink 270 through the module plate 250. The sink insulation material 280 may include a sink insulation material opening 281. In an embodiment, the sink insulation material 280 may be omitted, and in this case, the heat dissipation sink 220 may be supported by the upper surface of the module plate 250 and the cooling sink 270 may be supported by the bottom surface of the module plate 250.

The thermoelectric cooling device 200 may include a heat dissipation duct (not shown) that is provided to guide the air flowed by the heat dissipation fan 230. The heat dissipation duct may suck in the air out of the main body 100 and guides the air to exchange heat with the heat dissipation sink 220, and may discharge the heat-exchanged air with the heat dissipation sink 220 to the out of the main body 100.

The heat dissipation duct may suck in the air from the outer space on the upper side of the main body 100. The heat dissipation duct may discharge the air that has exchanged heat with the heat dissipation sink 220 to the outer space on the main body 100. The heat dissipation fan 230 may be located in the heat dissipation duct. The heat dissipation sink 220 may be located in the heat dissipation duct. The heat dissipation duct may be provided on the upper surface of the main body 100.

The thermoelectric cooling device 200 may include a cooling fan (not shown) that flows the air in a way such that the heat exchange between the cooling sink 270 and the inside of the storage chamber may be effectively performed. The cooling fan may be provided to blow toward the cooling sink 270. The cooling fan may be located in a horizontal direction from the cooling sink 270. The cooling fan may be provided in the storage chamber. The cooling fan may be provided at a lower side of the upper wall. The cooling fan may be a centrifugal fan that sucks in the air in an axial direction and discharges the air in a radial direction. The rotary shaft of the cooling fan may be arranged to be perpendicularly to the bottom surface of the upper wall.

The thermoelectric cooling device 200 may include a cooling duct (not shown) that is provided to guide the air flowed by the cooling fan. The cooling duct may suck in the air from the inside of the storage chamber and guides the air to exchange heat with the cooling sink 270, and discharge the air that has exchanged heat with the cooling sink 270 into the storage chamber. The cooling duct will hereinafter be described in detail with reference to FIG. 3.

FIG. 3 is a diagram showing the upper portion of the storage chamber in the refrigerator 1000 including the thermoelectric cooling device 200 according to an embodiment of the disclosure.

Referring to FIG. 3, in an embodiment, the thermoelectric cooling device 200 may include a cooling duct 300 provided to guide the air flowed by the cooling fan. The cooling duct 300 may suck in the air from the inside of the storage chamber and guides the air to exchange heat with the cooling sink 270, and discharge the air that has exchanged heat with the cooling sink 270 into the storage chamber.

The cooling fan may be located in the cooling duct 300. The cooling sink 270 may be located in the cooling duct 300. The cooling duct 300 may be provided on the lower surface of the upper wall.

The cooling duct 300 may include an internal air inlet port 301 that sucks in the air in the storage chamber into the cooling duct 300, and an internal air outlet port 302 that discharges the air that has exchanged heat with the cooling sink 270 into the storage chamber.

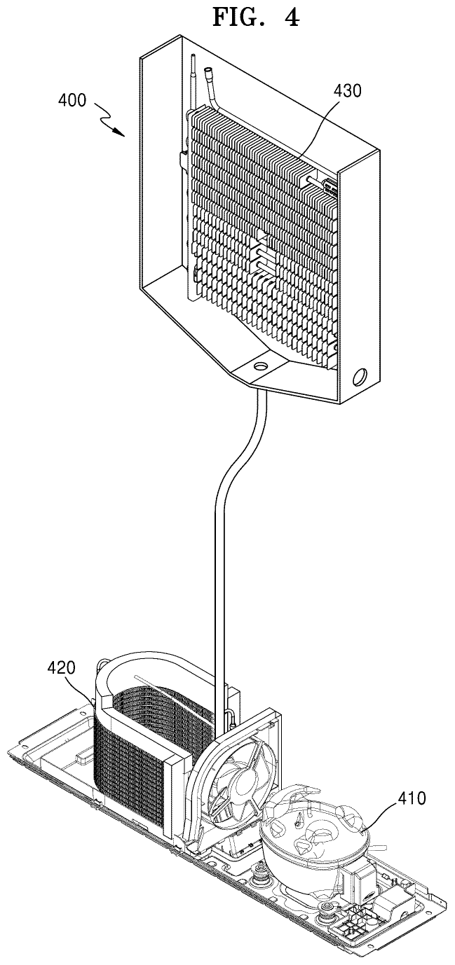

According to an embodiment of the disclosure, the refrigerator 1000 may further include a freezing cycle device further including a compressor, in addition to the thermoelectric cooling device 200. Hereinafter, the freezing cycle device will be described with reference to FIG. 4.

FIG. 4 is a diagram illustrating a freezing cycle device 400 according to an embodiment of the disclosure.

According to an embodiment of the disclosure, the refrigerator 1000 may include the freezing cycle device 400 that allows the storage chamber to be cooled down through a freezing cycle. The freezing cycle device 400 may include a compressor 410, a condenser 420, an expanding device (not shown), and an evaporator 430.

The compressor 410 compresses a refrigerant in high-temperature and high-pressure status. The compressor 410 may receive electrical energy from the outside and compress a gas-phase refrigerant with high-temperature and high-pressure by using a rotating force of an electrical motor, etc. The compressor 410 is connected to the condenser 420 and may move the compressed refrigerant to the condenser 420. The compressor 410 compresses the refrigerant and pushes the refrigerant to the condenser 420 and initiates a freezing cycle including compressing, condensing, expanding, and evaporating. Therefore, when the compressor 410 is driven, the cold air generated in the evaporator 430 is supplied to the storage chamber.

The condenser 420 condenses the refrigerant of high-pressure and high-temperature compressed by the compressor 410. The condenser 420 dissipates heat that is generated while condensing the refrigerant. The refrigerant that is condensed while passing through the condenser 420 is moved to an expansion valve (expansion device). The refrigerant condensed in the condenser 420 becomes a liquid phase of low-temperature and low-pressure while passing through the expansion valve. The liquid-phase refrigerant is moved to the evaporator 430 after passing through the expansion valve.

The evaporator 430 vaporizes the liquid-phase refrigerant of low-temperature and low-pressure that has passed through the expansion valve. In the evaporator 430, the liquid-phase refrigerant exchanges heat with peripheral gas while being vaporized. The liquid-phase refrigerant absorbs latent heat from the periphery, and accordingly, the gas around the evaporator 430 is cooled down and generates the cold air. The refrigerant that has completely vaporized is supplied into the compressor 410 again, and the cooling cycle circulates. A heater for removing frost from the evaporator 430 may be provided around the evaporator 430.

The refrigerator 1000 according to the embodiment of the disclosure includes the thermoelectric cooling device 200 and the freezing cycle device 400, and thus, may selectively drive at least one of the thermoelectric cooling device 200 or the freezing cycle device 400 in order to supply the cold air into the storage chamber. For example, the refrigerator 1000 may only supply the cold air generated by the thermoelectric cooling device 200 into the storage chamber, only supply the cold air generated by the freezing cycle device 400 into the storage chamber, and may supply the cold air generated by the thermoelectric cooling device 200 and the cold air generated by the freezing cycle device 400 into the storage chamber.

According to an embodiment of the disclosure, the refrigerator 1000 may supply the cold air to the storage chamber by appropriately controlling the thermoelectric cooling device 200 or the freezing cycle device 400 according to an operating environment of the refrigerator 1000 (external condition or internal condition). For example, when the indoor temperature of the space where the refrigerator 1000 is installed is higher than a certain temperature and the cooling through the freezing cycle device 400 is more effective than the cooling through the thermoelectric cooling device 200, the refrigerator 1000 may cool down the storage chamber only with the cold air generated by the freezing cycle device 400. On the contrary, when the indoor temperature is less than a certain temperature and the cooling through the thermoelectric cooling device 200 is more effective than the cooling through the freezing cycle device 400, the refrigerator 1000 may cool down the storage chamber only with the cold air generated by the thermoelectric cooling device 200. When it is desired to reduce noise, the refrigerator 1000 may only drive the thermoelectric cooling device 200. When it is desired to rapidly cool down the storage chamber, the refrigerator 1000 may supply the cold air generated by the thermoelectric cooling device 200 and the cold air generated by the freezing cycle device 400 simultaneously to the storage chamber. For example, when the storage chamber is packed with food and desired to be rapidly cooled down, the refrigerator 1000 may simultaneously operate the thermoelectric cooling device 200 and the freezing cycle device 400.

In addition, the refrigerator 1000 may use the thermoelectric cooling device 200 to maintain the storage chamber at a constant temperature. For example, when the freezing cycle device 400 is driven and a critical set temperature (e.g., 0° C.) has reached, the refrigerator 1000 stops operating the freezing cycle device 400 and drive the thermoelectric cooling device 200. Because the thermoelectric cooling device 200 may not has a large cooling efficiency, the temperature of the storage chamber may be maintained around the critical set temperature (e.g., 0° C.).

In addition, according to an embodiment of the disclosure, the refrigerator 1000 may include the thermoelectric cooling device 200 and the freezing cycle device 400, but is not limited thereto, and the refrigerator 1000 may only include the thermoelectric cooling device 200.

Hereinafter, arrangement of internal elements of the thermoelectric module 210 for preventing the loss of entire function of the thermoelectric cooling device 200 due to one defective internal element included in the thermoelectric cooling device 200 will be described in detail with reference to FIGS. 5A to 8.

FIG. 5A is a diagram illustrating a thermoelectric module 210 with internal elements classified in two groups, according to an embodiment of the disclosure.

Referring to FIG. 5A, the thermoelectric module 210 may have internal elements that are classified in a plurality of groups. Here, the internal elements in each group may be connected to each other in series. For example, the thermoelectric module 210 may include a first group 510 including first internal elements, and a second group 520 including second internal elements. Here, the first internal elements included in the first group 510 may be connected to each other in series in the first group 510, and the second internal elements included in the second group 520 may be connected to each other in series in the second group 520.

According to an embodiment of the disclosure, the plurality of groups may be connected in parallel with each other to a power line connected to the thermoelectric module 210. For example, the plurality of groups may be connected in parallel between a positive (+) power line and a negative (−) power line connected to opposite ends of the thermoelectric module 210. That is, the plurality of groups may be tied to one start point and one end point such that each of the groups may be connected in parallel. For example, a start point of an arrangement of the internal elements in each of the plurality of groups may be connected to the positive (+) power line and an end point of the arrangement of the internal elements in each of the plurality of groups may be connected to the negative (−) power line. Alternatively, a start point of the arrangement of the internal elements in each of the plurality of groups may be connected to the negative (−) power line and an end point of the arrangement of the internal elements in each of the plurality of groups may be connected to the positive (+) power line. Here, the plurality of groups may commonly use the positive (+) power line and the negative (−) power line, and thus, the shape of the thermoelectric module 210 may be simplified as compared with a case in which a few power lines are extending from each group. Hereinafter, unless otherwise defined, the ‘power line’ may be a concept including the positive (+) power line and the negative (−) power line.

In an embodiment, as shown in FIG. 5A, the plurality of groups may be connected in parallel between the positive (+) power line and the negative (−) power line, but the disclosure is not limited thereto. For example, when the positive (+) power line and the negative (−) power line are collectively arranged on one side, the plurality of groups may not be arranged between the positive (+) power line and the negative (−) power line.

In an embodiment, where the plurality of groups is connected in parallel with each other to the power line, the electrical connection between the internal elements included in different groups from each other may be blocked. For example, the plurality of groups may include the first group 510 and the second group 520, and the first internal elements of the first group 510 and the second internal elements in the second group 520 may not be electrically connected to each other except for an input node and an output node thereof. That is, a current direction of the first group 510 and a current direction of the second group 520 may be different from each other. That is, a current path of a current flowing through the first group 510 and a current path of a current flowing through the second group 520 may be branched off from the positive (+) power line. Therefore, when there is a defect occurring in one of the first internal elements of the first group 510, it may not affect the current flow among the second internal elements in the second group 520. Hereinafter, a case in which at least one of the plurality of groups loses a function will be described in detail with reference to FIG. 5B.

FIG. 5B is a diagram for describing functions of a thermoelectric module 210 with internal elements classified in two groups, according to an embodiment of the disclosure.

Referring to FIG. 5B, in an embodiment where the plurality of groups is connected in parallel with each other to the power line, even when there is a defect in one of the internal elements, one group including the one of the internal elements may lose a function, but other groups may normally perform the functions of the thermoelectric module 210. For example, when there is a defect in one of the first internal elements included in the first group 510, the first group 510 loses a function, but the second group 520 normally operates. Thus, the cooling function of the thermoelectric module 210 may be maintained. Therefore, according to an embodiment of the disclosure, even when an open defect occurs in one of hundreds of internal elements, the thermoelectric module 210 may retain the cooling function of minimum 50%.

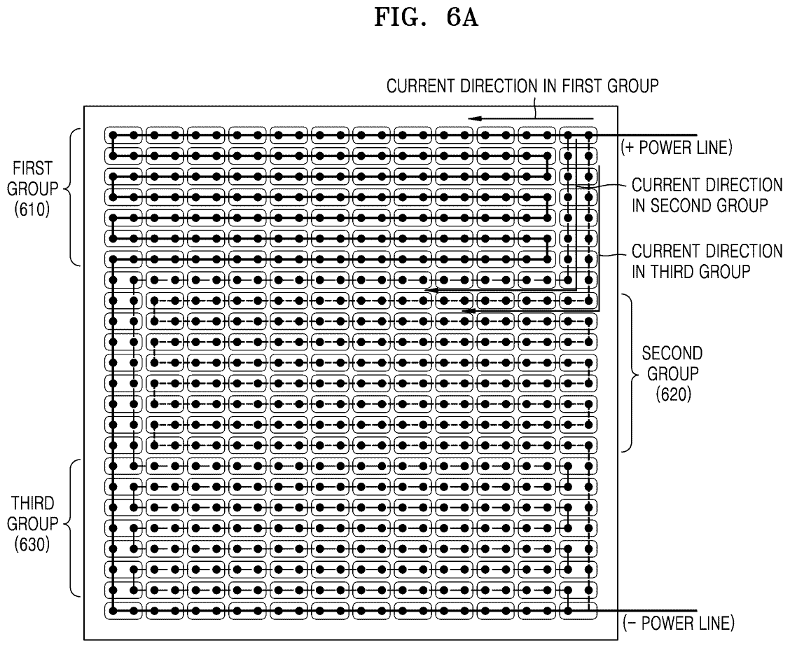

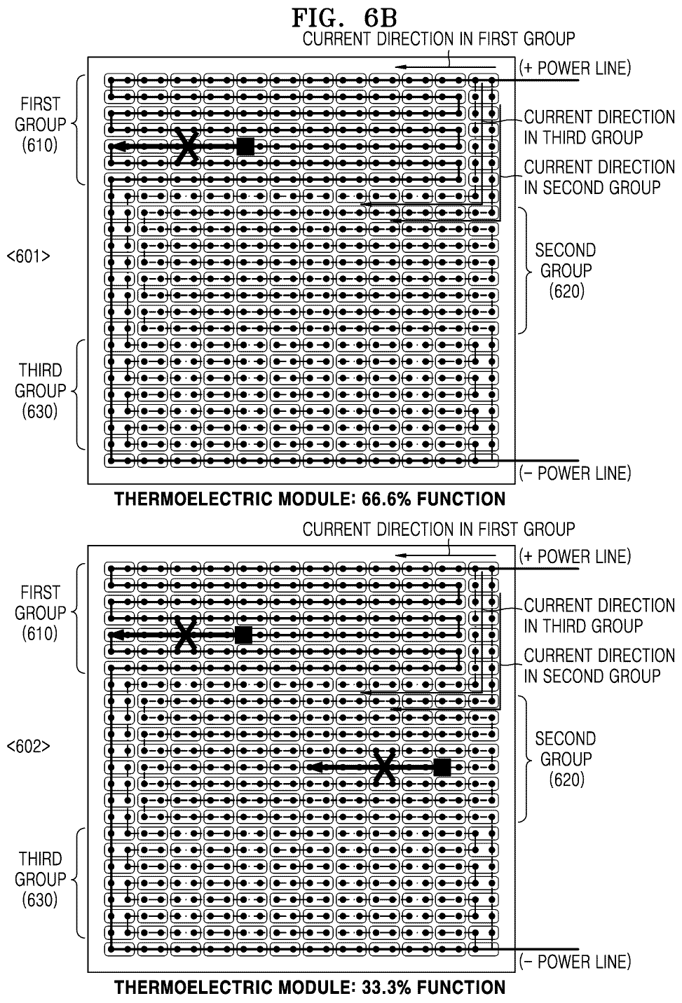

FIGS. 5A and 5B show an embodiment in which the internal elements are grouped in two groups, but the embodiment of the disclosure is not limited thereto. In an embodiment, for example, the internal elements may be provided in three groups. Referring to FIGS. 6A and 6B, an embodiment in which the internal elements of the thermoelectric module 210 are provided in three groups, will hereinafter be described.

FIG. 6A is a diagram illustrating a thermoelectric module 210 with internal elements classified in three groups, according to an embodiment of the disclosure.

Referring to FIG. 6A, in an embodiment, the thermoelectric module 210 may include internal elements that are classified in three groups. The internal elements in each group may be connected in series. For example, the internal elements of the thermoelectric module 210 may be classified in a first group 610, a second group 620, and a third group 630. Here, the first internal elements included in the first group 610 may be connected to each other in series in the first group 610, the second internal elements included in the second group 620 may be connected to each other in series in the second group 620, and third internal elements included in the third group 630 may be connected to each other in series in the third group 630.

The first group 610, the second group 620, and the third group 630 may be connected in parallel with each other between a positive (+) power line and a negative (−) power line connected to opposite ends of the thermoelectric module 210. That is, the first group 610, the second group 620, and the third group 630 may be connected in parallel with each other between one start point and one end point. For example, in each of the first group 610, the second group 620, and the third group 630, a start point of the arrangement of the internal elements therein may be connected to the positive (+) power line, and an end point of the arrangement of the internal elements therein may be connected to the negative (−) power line. Alternatively, in each of the first group 610, the second group 620, and the third group 630, a start point of the arrangement of the internal elements therein may be connected to the negative (−) power line, and an end point of the arrangement of the internal elements therein may be connected to the positive (+) power line. Here, the first group 610, the second group 620, and the third group 630 may commonly use the power line, and thus, a separate power line may not be provided for each group.

In an embodiment, the first internal elements in the first group 610, the second internal elements in the second group 620, and the third internal elements in the third group 630 may not be electrically connected to one another except for an input node and an output node thereof. That is, the current direction in the first group 610, the current direction in the second group 620, and the current direction in the third group 630 may be different from one another. Therefore, even when a defect occurs in one of the first internal elements of the first group 610, the defect may not affect the second group 620 and the third group 630. Hereinafter, a case in which at least one of the three groups loses a function will be described in detail with reference to FIG. 6B.

FIG. 6B is a diagram for describing functions of a thermoelectric module 210, in which internal elements are classified in three groups, according to an embodiment of the disclosure.

Referring to 601 of FIG. 6B, when an open defect occurs in one of the first internal elements included in the first group 610, the first group 610 loses a function, but the second group 620 and the third group 630 normally operate. Thus, the cooling function of the thermoelectric module 210 may be maintained. That is, the thermoelectric module 210 including three groups may retain the cooling function of 66.6%, even when an open defect occurs in one of the hundreds of internal elements.

Referring to 602 of FIG. 6B, when an open defect occurs in one of the first internal elements included in the first group 610 and an open defect occurs in one of the second internal elements included in the second group 620, the first group 610 and the second group 620 lose functions, but the third group 630 normally operates. Thus, the cooling function of the thermoelectric module 210 may be maintained. That is, the thermoelectric module 210 including three groups may retain the cooling function of 33.3% even when two groups lose functions.

Therefore, as the thermoelectric module 210 is classified into more groups, a ratio of losing the function of the thermoelectric module 210 due to one defective element may decrease. However, as the number of groups increases, the resistance of the thermoelectric module 210 is decreased and the current amount of the thermoelectric module 210 may increase. Therefore, it may be effective that the thermoelectric module 210 is classified into an appropriate number of groups (e.g., two or three groups) to prevent an overcurrent from flowing in the thermoelectric module 210.

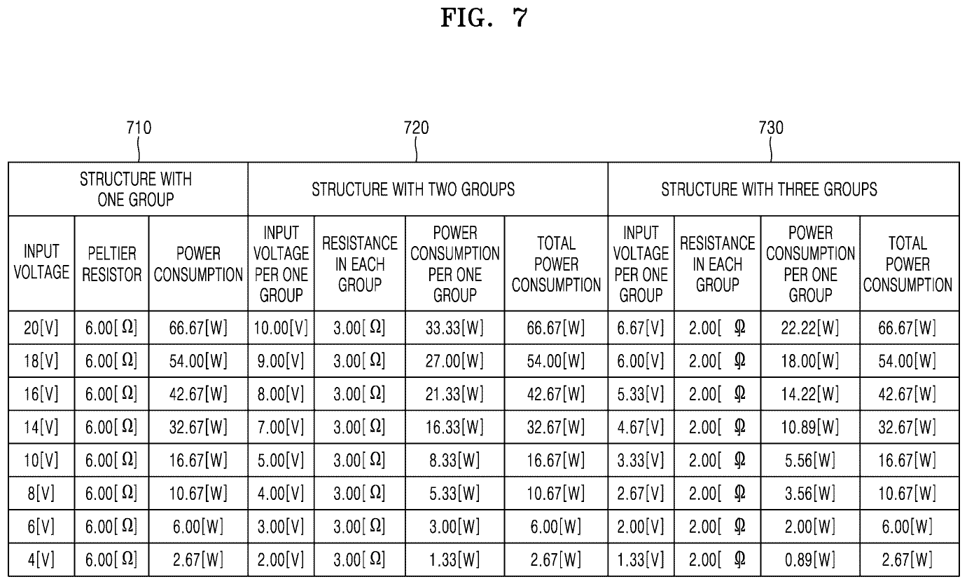

FIG. 7 is a table for describing changes in a voltage and resistance when internal elements of the thermoelectric module 210 according to an embodiment of the disclosure are grouped into a plurality of groups.

Referring to FIG. 7, in a general case (710) in which the thermoelectric module 210 includes only one group or a single group, when an input voltage is 20 volts (V) and a resistance of the thermoelectric module 210 is 6 ohms (Ω), a power consumption of the thermoelectric module 210 is 66.67 W and a current in the thermoelectric module 210 may be 3.3 ampere (A).

In case where the thermoelectric module 210 is divided into two groups (720), when a voltage 20 V is applied to the thermoelectric module 210, the input voltage to each group may be 10 V, and the resistance of each group may be 3Ω. Therefore, the power consumption for each group is 33.33 W and the total power consumption of the two groups may be 66.67 W. In addition, because two groups are connected in parallel, the total resistance of the thermoelectric module 210 may be 1.5Ω, and the current in the thermoelectric module 210 may be 13.3 A.

In case where the thermoelectric module 210 is divided into three groups (730), when a voltage 20 V is applied to the thermoelectric module 210, the input voltage to each group may be 6.67 V, and the resistance of each group may be 2Ω. Therefore, the power consumption for each group is 22.22 W and the total power consumption of the three groups may be 66.67 W. In addition, because three groups are connected in parallel, the total resistance of the thermoelectric module 210 may be 1.3Ω, and the current in the thermoelectric module 210 may be 15.4 A.

That is, the plurality of groups is connected with each other in parallel, the input voltage applied to the thermoelectric module 210 may be divided according to the number of groups, and the total power consumption may be consistently maintained regardless of the number of groups. Also, as the number of groups increases, the total resistance of the thermoelectric module 210 decreases and the current amount may increase.

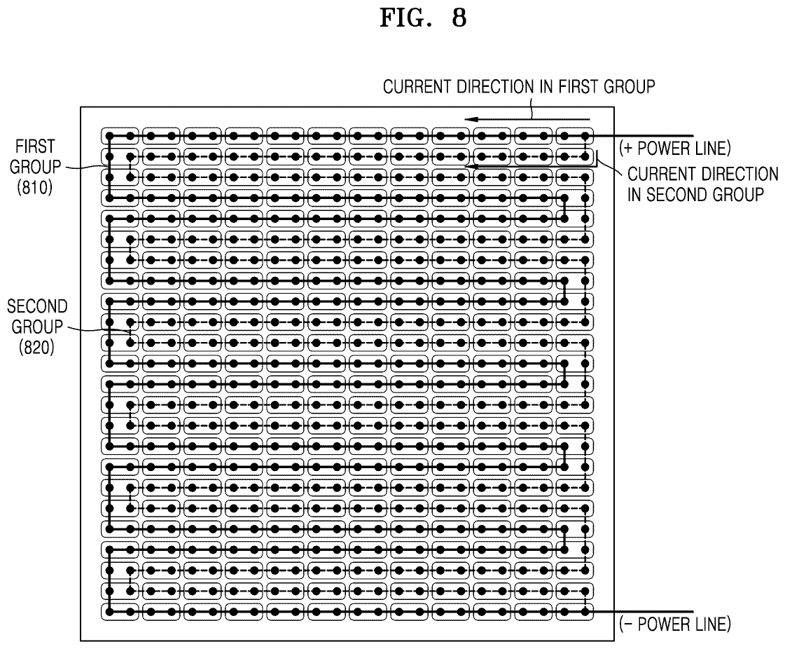

In addition, according to an embodiment of the disclosure, the internal elements included in each of the plurality of groups may be arranged to be distributed throughout the entire area of the thermoelectric module 210. Referring to FIG. 8, the arrangement of the internal elements that are distributed throughout the entire thermoelectric module 210 will hereinafter be described.

FIG. 8 is a diagram for describing an arrangement of internal elements included in the thermoelectric module 210 according to an embodiment of the disclosure.

Referring to FIG. 8, the first internal elements included in the first group 810 and the second internal elements included in the second group 820 may be arranged to be distributed throughout the entire thermoelectric module 210 in a matrix form. For example, the first internal elements included in the first group 810 and the second internal elements included in the second group 820 may be arranged alternately with each other based on rows or columns. In FIG. 8, an embodiment in which two lines of the first internal elements and two lines of the second internal elements are alternately arranged is shown, but the embodiment of the disclosure is not limited thereto. In an embodiment, one line of the first internal elements and one line of the second internal elements may be alternately arranged, or three lines of the first internal elements and three lines of the second internal elements may be alternately arranged.

In a case where the first internal elements of the first group 810 and the second internal elements of the second group 820 are arranged in distinguished regions (e.g., upper and lower regions, or left and right regions), a partial region of the cooling portion 212 (see FIG. 2) in which the second internal elements of the second group 820 may be only cooled down when the first group 810 loses a function thereof. On the other hand, when the first internal elements of the first group 810 and the second internal elements of the second group 820 are arranged to be distributed throughout the entire thermoelectric module 210, the cooling portion 212 may be entirely cooled down even when the first group 810 loses a function.

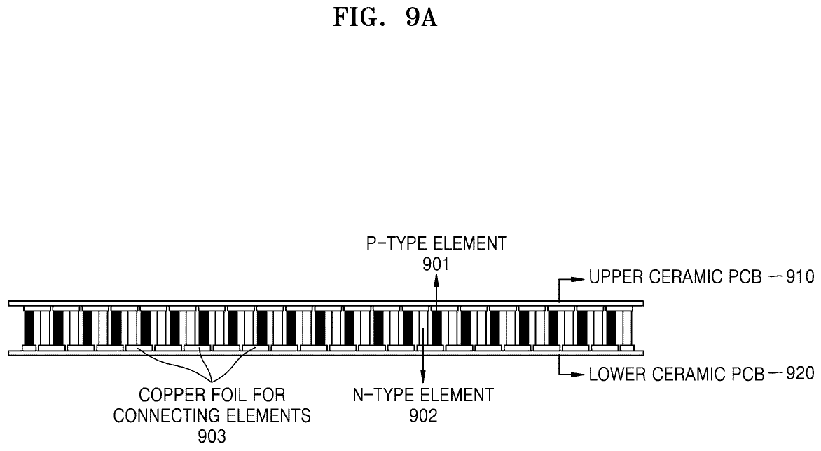

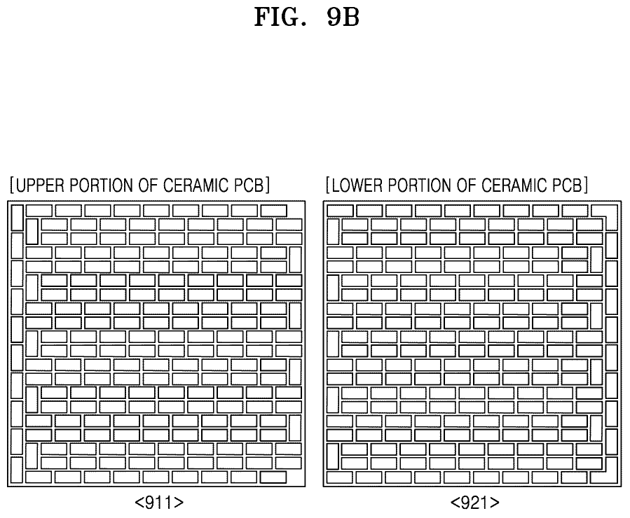

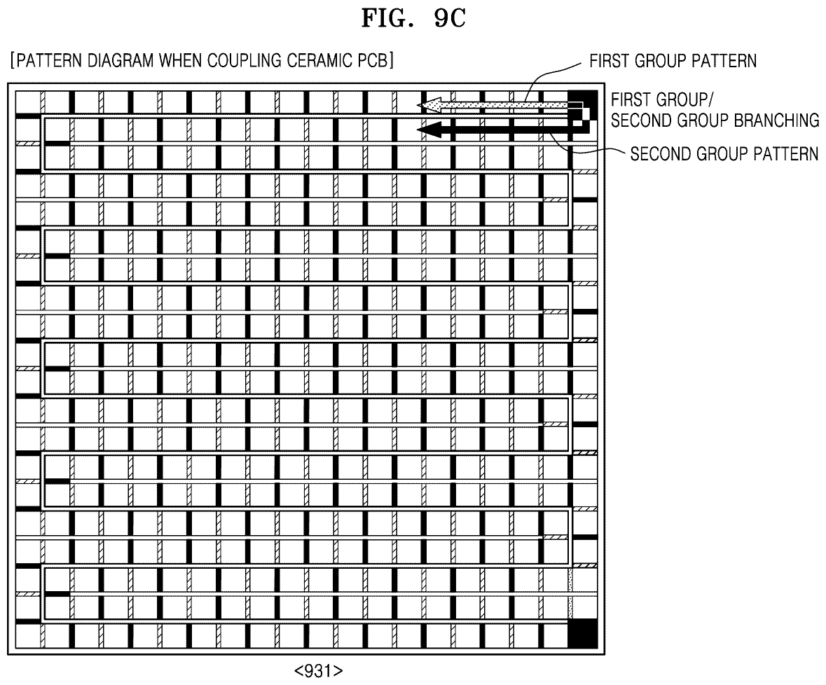

Hereinafter, referring to FIGS. 9A to 9C, the arrangement of the internal elements in the thermoelectric module 210 will be described in greater detail.

FIG. 9A is a diagram for describing a structure of the thermoelectric module 210 according to an embodiment of the disclosure.

Referring to FIG. 9A, in an embodiment, the thermoelectric module 210 may include an upper substrate 910 (e.g., upper ceramic printed circuit board (PCB)), a lower substrate 920 (e.g., lower ceramic PCB), P-type elements 901, and N-type elements 902. Each of the upper substrate 910 and the lower substrate 920 may include copper foils 903 for connecting the P-type elements 901 or the N-type elements 902. The P-type elements 901 and the N-type elements 902 may be arranged perpendicularly between the upper substrate 910 and the lower substrate 920 or arranged vertically with respect to opposing surfaces of the upper substrate 910 and the lower substrate 920. Also, the P-type elements 901 and the N-type elements 902 may be alternately arranged, and the P-type element 901 and the N-type element 902 may be connected to each other in series. This arrangement is provided in a way such that the heat may move in only one direction while the electricity flows continuously flows through the upper substrate 910 and the lower substrate 920 in alternate manner through the P-type elements 901 and the N-type elements 902. For example, according to the arrangement of the internal elements shown in FIG. 9A, the lower substrate 920 may be the cooling portion 212 (see FIG. 2), and the upper substrate 910 may be the heating portion 211 (see FIG. 2).

Hereinafter, a pattern diagram of the copper foils in the upper substrate 910 and the lower substrate 920 in an embodiment where the thermoelectric module 210 is divided into a plurality of groups will be described below with reference to FIG. 9B.

FIG. 9B is a diagram describing a substrate pattern in the thermoelectric module 210 according to an embodiment of the disclosure.

According to an embodiment of the disclosure, a copper foil pattern diagram 911 of the upper substrate 910 and a copper foil pattern diagram 921 of the lower substrate 920 may be designed in order for the internal elements of the thermoelectric module 210 to be provided in a plurality of groups connected in parallel with each other. Here, the copper foil pattern diagram 911 of the upper substrate 910 and the copper foil pattern diagram 921 of the lower substrate 920 may be designed in a way such that the first internal elements included in the first group and the second internal elements included in the second group may be arranged to be distributed throughout the entire substrate. For example, the copper foil pattern diagram 911 of the upper substrate 910 and the copper foil pattern diagram 921 of the lower substrate 920 may be designed in a way such that two lines of the first internal elements and two lines of the second internal elements are alternately arranged.

FIG. 9C is a diagram describing a pattern during substrate coupling in the thermoelectric module 210 according to an embodiment of the disclosure.

Referring to a pattern diagram 931 when the upper substrate 910 and the lower substrate 920 are coupled to each other shown in FIG. 9C, the internal elements included in the thermoelectric module 210 may be provided in the first group and the second group, and the first group and the second group may be connected in parallel with each other to the power line. That is, the first group and the second group may commonly use or be connected to one power line, e.g., a single positive (+) power line and a single negative (−) power line. In such an embodiment, the input node of the first group and the input node of the second group are the same are each other, and the output node of the first group and the output node of the second group are the same are each other. For example, a start point of the arrangement of the internal elements in each of the first and second groups may be connected to the positive (+) power line and an end point of the arrangement of the internal elements in each of the first and second groups may be connected to the negative (−) power line.

In addition, the first internal elements included in the first group may be connected to each other in series in the first group, and the second internal elements included in the second group may be connected to each other in series in the second group. Also, the first internal elements included in the first group and the second internal elements included in the second group may be arranged to be distributed throughout the entire thermoelectric module 210.

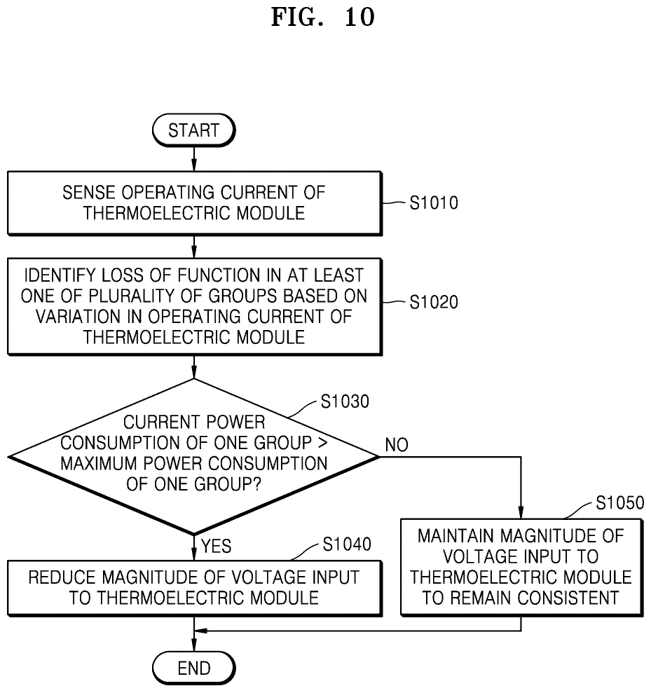

According to an embodiment of the disclosure, where the internal elements in the thermoelectric module 210 are provided as a plurality of groups, even though one group has lost a function, the remaining groups may effectively perform the function. Also, the refrigerator 1000 may sense the state in which at least one of the plurality of groups has an open defect through sensing the current of the thermoelectric module 210, and controls the input voltage to the thermoelectric module 210 to compensate for the lost function. Hereinafter, an embodiment of the method for the refrigerator 1000 to control the thermoelectric module 210 will be described in detail with reference to FIG. 10.

FIG. 10 is a flowchart illustrating the method, performed by the refrigerator 1000, of controlling the thermoelectric module 210, according to an embodiment of the disclosure.

Referring to FIG. 10, an embodiment of the method of controlling the thermoelectric module 210 by the refrigerator 1000 may include operation S1010 to operation S1050. In the embodiment of the disclosure, operation S1010 to operation S1050 may be executed by at least one processor included in the refrigerator 1000. Embodiments of the method of controlling the thermoelectric module 210 by the refrigerator 1000 are not limited to the example shown in FIG. 10, and the method may further include operations not shown in FIG. 10 or some of the operations shown in FIG. 10 may be omitted.

In operation S1010, the refrigerator 1000 according to the embodiment of the disclosure may sense an operating current of the thermoelectric module 210 when the thermoelectric module 210 operates. For example, the refrigerator 1000 may sense the operating current of the thermoelectric module 210 by using a current sensing circuit. The current sensing circuit may include, but is not limited to, a shunt resistor.

According to an embodiment of the disclosure, the current sensing circuit may be included in a printed board assembly (or printed circuit board assembly (PBA)) of the power supply device for supplying the power to the thermoelectric module 210, or may be included in a PBA on which a processor for controlling the thermoelectric module 210 is mounted.

In operation S1020, the refrigerator 1000 according to an embodiment of the disclosure may identify loss of the function in at least one of the plurality of groups, based on a variation in the operating current of the thermoelectric module 210.

According to an embodiment of the disclosure, where the thermoelectric module 210 includes the first group and the second group and one P or N-type element included in the first group is damaged, the electric current may not further flow in the first group. Therefore, the total resistance of the thermoelectric module 210 may be reduced to half, and the operating current of the thermoelectric module 210 may be increased by twice. Here, the refrigerator 1000 senses that the operating current of the thermoelectric module 210 increases twice, and may identify that one of the two groups has lost a function.

In an embodiment, where the thermoelectric module 210 includes the first group, the second group, and the third group, and one P or N-type element included in the second group is damaged, the electric current may not further flow in the second group. Therefore, the total resistance of the thermoelectric module 210 may be reduced by about 30%, and the operating current of the thermoelectric module 210 may be increased by about 30%. The refrigerator 1000 may sense that the operating current of the thermoelectric module 210 increases, and identify that one of the three groups has lost a function. Also, when one element included in the first group and one element included in the second group are damaged, the total resistance of the thermoelectric module 210 may be reduced by about 60% and the operating current may be increased by about 60%. The refrigerator 1000 may sense that the operating current of the thermoelectric module 210 rapidly increases, and may identify that two of the three groups have lost the functions.

According to an embodiment of the disclosure, when the operating current of the thermoelectric module 210 is zero (0) A, the refrigerator 1000 may identify that all of the groups included in the thermoelectric module 210 have lost the functions.

In operation S1030, when it is identified that at least one of the plurality of groups included in the thermoelectric module 210 has lost a function, the refrigerator 1000 may determine whether a current power consumption of one group exceeds the maximum power consumption of one group.

According to an embodiment of the disclosure, when at least one of the plurality of groups has lost a function, the voltage distributed to at least one group may be applied to remaining groups. Therefore, more voltage is applied to the other groups that do not lose the functions. Here, the refrigerator 1000 may determine whether the current power consumption of one group exceeds the maximum power consumption of one group to prevent the other groups that do not lose the functions from being in an over-voltage status. According to an embodiment of the disclosure, because the plurality of groups commonly use the power line, the refrigerator 1000 may not monitor the operating current of each of the plurality of groups, and thus, it may be difficult to identify which one of the plurality of groups has lost a function. Therefore, the refrigerator 1000 may compare the current power consumption with the maximum power consumption of one arbitrary group.

For example, when the thermoelectric module 210 includes two groups and one of the two groups has lost a function, the power consumption of the other group may increase twice. Therefore, the refrigerator 1000 may determine whether the increased current power consumption exceeds the maximum power consumption set in advance per each group. The maximum power consumption per group may be set in advance based on operating conditions of the thermoelectric module 210.

In operation S1040, when the current power consumption of one group exceeds the maximum power consumption of one group (Yes to operation S1030), the refrigerator 1000 may reduce the magnitude of the voltage applied to the thermoelectric module 210 to be low.

According to an embodiment of the disclosure, when the current power consumption of one group exceeds the maximum power consumption of one group, the thermoelectric module 210 may be in an over-voltage status. When an over-voltage is applied to the thermoelectric module 210, the cooling portion 212 of the thermoelectric module 210 may not be cooled down, but the thermoelectric module 210 may become hotter entirely.

Therefore, the refrigerator 1000 may reduce the magnitude of the voltage input to the thermoelectric module 210 to be low, such that the current power consumption is less than or equal to the maximum power consumption. For example, when the maximum power consumption is 50 W and the current power consumption of the thermoelectric module 210 is sensed as 100 W, the refrigerator 1000 may reduce the magnitude of the voltage input to the thermoelectric module 210 into half. In addition, the refrigerator 1000 may identify whether the voltage input to the thermoelectric module 210 is reduced to half via the voltage sensing circuit. The voltage sensing circuit may include a voltage distribution circuit, but is not limited thereto.

In operation S1050, the refrigerator 1000 according to an embodiment of the disclosure may maintain the magnitude of the voltage input to the thermoelectric module 210 to remain consistent, when the current power consumption of one group does not exceed the maximum power consumption of one group (No to operation S1030).

For example, even when at least one of the plurality of groups has lost a function and the power consumption of one group increases, the refrigerator 1000 may maintain the current voltage status without adjusting the magnitude of the voltage input to the thermoelectric module 210 provided that the increased power consumption does not exceed the maximum power consumption. That is, when an open defect occurs in certain group of the plurality of groups, the lost function of the thermoelectric module 210 may be covered by further applying the voltage to the other groups.

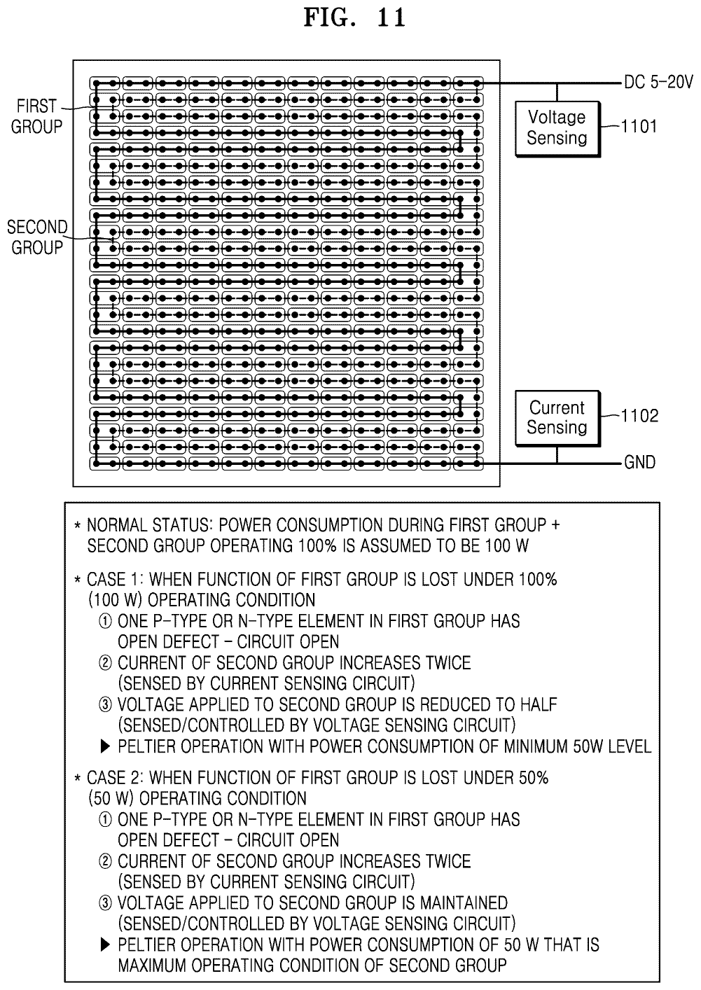

Hereinafter, referring to FIG. 11, an example in which the refrigerator 1000 controls the magnitude of the voltage input to the thermoelectric module 210 when at least one of the plurality of groups of the thermoelectric module 210 has lost a function will be described in detail.

FIG. 11 is a diagram for describing an operation of the refrigerator 1000 for controlling the thermoelectric module 210 by using a voltage sensing circuit 1101 and a current sensing circuit 1102.

Referring to FIG. 11, in an embodiment, the thermoelectric module 210 may include the voltage sensing circuit 1101 and the current sensing circuit 1102. The voltage sensing circuit 1101 and the current sensing circuit 1102 may be included in the PBA of the power supply device for supplying power to the thermoelectric module 210 or may be included in the PBA on which a processor for controlling the thermoelectric module 210 is mounted. The processor of the refrigerator 1000 may identify the voltage value input to the thermoelectric module 210 via the voltage sensing circuit 1101 and sense the operating current of the thermoelectric module 210 via the current sensing circuit 1102.

In an embodiment, as shown in FIG. 11, the internal elements of the thermoelectric module 210 are classified in the first group and the second group, and when the first group and the second group operate 100%, the power consumption of the thermoelectric module 210 may be 100 W, for example. Also, it is assumed that the voltage input to the thermoelectric module 210 is 20 V and a resistance of each group is 2. When the first group and the second group operate 100%, the power consumption of each group may be up to 50 W. That is, the maximum power consumption of one group in FIG. 11 may be 50 W.

According to Case 1, under a condition in which the thermoelectric module 210 operates 100% (total power consumption: 100 W, power consumption of first group: 50 W, and power consumption of second group: 50 W), the first group may lose a function. For example, an open defect may occur in one P or N-type element in the first group. Here, the current of the second group may increase twice, and the processor of the refrigerator 1000 may sense that the operating current of the thermoelectric module 210 increases twice by using the current sensing circuit 1101. When the current of the second group increases twice, the power consumption of the second group may also increase twice. That is, the power consumption of the second group may increase from 50 W to 100 W. When the power consumption of the second group is 100 W, the power consumption exceeds the maximum power consumption of the second group, that is, 50 W, the second group may be in an over-voltage status. Therefore, the processor of the refrigerator 1000 may reduce the voltage input to the thermoelectric module 210 to half such that the second group may operate with the power consumption of 50 W. For example, the processor of the refrigerator 1000 may reduce the voltage input to the thermoelectric module 210 from 20 V to 10 V. Therefore, according to Case 1, even when an open defect occurs in the first group, the thermoelectric module 210 may act with 50% or greater performance.

According to Case 2, under a condition in which the thermoelectric module 210 operates at 50% (total power consumption: 50 W, power consumption of first group: 25 W, and power consumption of second group: 25 W), the first group may lose a function. For example, an open defect may occur in one P or N-type element in the first group. Here, the current of the second group may increase twice, and the processor of the refrigerator 1000 may sense that the operating current of the thermoelectric module 210 increases twice by using the current sensing circuit 1101. When the current of the second group increases twice, the power consumption of the second group may also increase twice. That is, the power consumption of the second group may increase from 25 W to 50 W. Even when the power consumption of the second group increases to 50 W, the power consumption does not exceed the maximum power consumption of the second group, that is, 50 W, and thus, the processor of the refrigerator 1000 may maintain the voltage input to the thermoelectric module 210 to remain consistent. Therefore, according to Case 2, even when the first group has lost a function, the thermoelectric module 210 may satisfy the condition of operating at 50% (total power consumption: 50 W) by means of the second group.

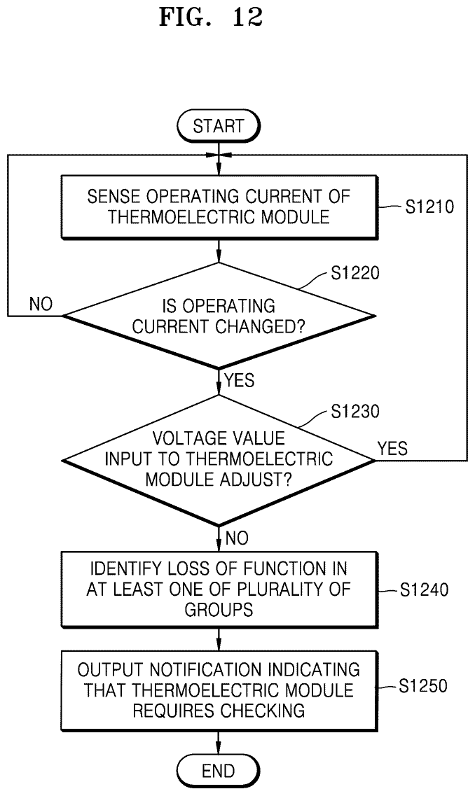

FIG. 12 is a flowchart of a method of a refrigerator to output a notification indicating that a thermoelectric module requires checking, according to an embodiment of the disclosure.

Referring to FIG. 12, an embodiment of the method of outputting the notification indicating that the thermoelectric module 210 requires checking (or that the thermoelectric module 210 does not normally operate) from the refrigerator 1000 may include operation S1210 to operation S1250. In an embodiment of the disclosure, operation S1210 to operation S1250 may be executed by at least one processor included in the refrigerator 1000. Embodiments of the method of controlling the thermoelectric module 210 by the refrigerator 1000 are not limited to the example shown in FIG. 12, and the method may further include operations not shown in FIG. 12 or some of the operations shown in FIG. 12 may be omitted.

In operation S1210, the refrigerator 1000 according to an embodiment of the disclosure may sense an operating current of the thermoelectric module 210 when the thermoelectric module 210 operates. For example, the refrigerator 1000 may sense the operating current of the thermoelectric module 210 by using the current sensing circuit 1102.

In operation S1220, the refrigerator 1000 according to an embodiment of the disclosure may sense the variation in the operating current of the thermoelectric module 210 by using the current sensing circuit.

In operation S1230, the refrigerator 1000 according to an embodiment of the disclosure may determine whether the voltage value input to the thermoelectric module 210 is being adjusted when sensing the variation in the operating current of the thermoelectric module 210 (Yes to operation S1220).

When the processor of the refrigerator 1000 is adjusting the voltage value input to the thermoelectric module 210, it may be natural that the operating current of the thermoelectric module 210 changes. Therefore, the processor of the refrigerator 1000 may continuously monitor whether the operating current of the thermoelectric module 210 changes while adjusting the voltage value input to the thermoelectric module 210.

In operation S1240, when the refrigerator 1000 according to an embodiment of the disclosure is not adjusting the voltage value input to the thermoelectric module 210 (No to operation S1230), and when sensing the variation in the operating current of the thermoelectric module 210 (Yes to operation S1220), the refrigerator 1000 may identify that at least one of the plurality of groups included in the thermoelectric module 210 has lost a function.

According to an embodiment of the disclosure, when the thermoelectric module 210 includes the first group and the second group and one P or N-type element included in the first group is damaged, the electric current may not further flow in the first group. Therefore, the total resistance of the thermoelectric module 210 may be reduced to half, and the operating current of the thermoelectric module 210 may be increased twice. Here, the refrigerator 1000 senses that the operating current of the thermoelectric module 210 increases twice, and may identify that one of the two groups has lost a function.

Because operation S1240 corresponds to operation S1020 of FIG. 10, any repetitive detailed descriptions thereof will be omitted.

In operation S1250, when identifying that at least one of the plurality of groups included in the thermoelectric module 210 has lost a function, the refrigerator 1000 according to the embodiment of the disclosure may output a notification indicating that the thermoelectric module 210 has to be checked or requires checking.

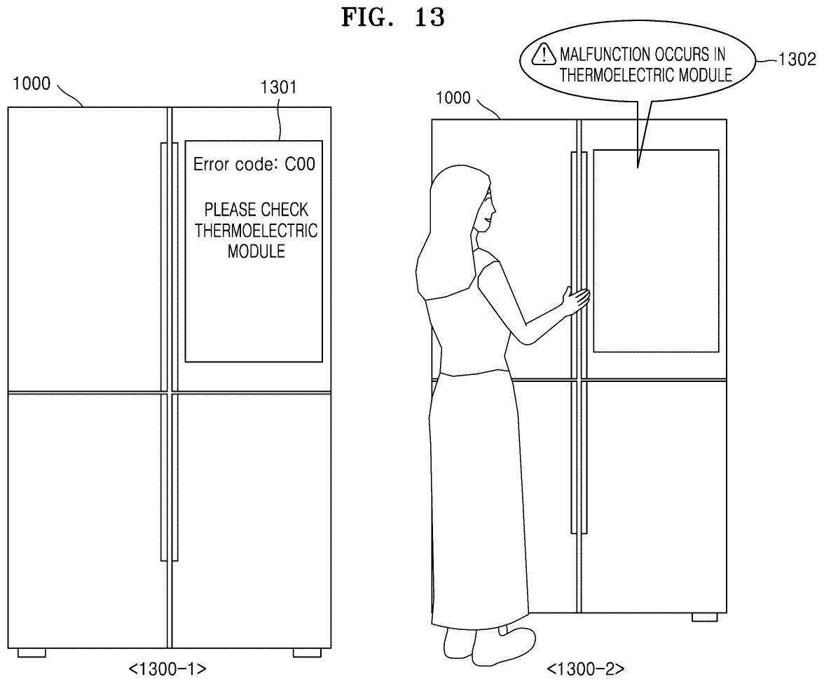

According to an embodiment of the disclosure, the refrigerator 1000 may output the notification indicating the thermoelectric module 210 requires checking through a display unit or a speaker. An example in which the refrigerator 1000 outputs the notification will hereinafter be described with reference to FIG. 13.

FIG. 13 is a diagram describing an operation of the refrigerator 1000 to output a notification indicating that a thermoelectric module requires checking, according to an embodiment of the disclosure.

In 1300-1 of FIG. 13, in an embodiment where the refrigerator 1000 includes a display unit, the refrigerator 1000 may visually display a notification indicating that the thermoelectric module 210 requires checking on the display unit. For example, when sensing that at least one of the plurality of groups included in the thermoelectric module 210 has lost a function, the refrigerator 1000 may display a notification message 1301 (e.g., check the thermoelectric module) along with an error code (e.g., C00) on the display unit.

Referring to 1300-2 of FIG. 13, in an embodiment, the refrigerator 1000 may audibly output a notification indicating that the thermoelectric module 210 requires checking through a speaker. For example, when sensing that a user approaches the refrigerator 1000 via a human sensor, the refrigerator 1000 may output a notification message (e.g., there is an error in the function of the thermoelectric module) 1302 as voice through the speaker.

According to an embodiment of the disclosure, the user identifies the notification output from the refrigerator 1000 and may get the thermoelectric module 210 checked. Therefore, degradation in the cooling performance of the storage chamber due to the thermoelectric module 210 may be effectively prevented.

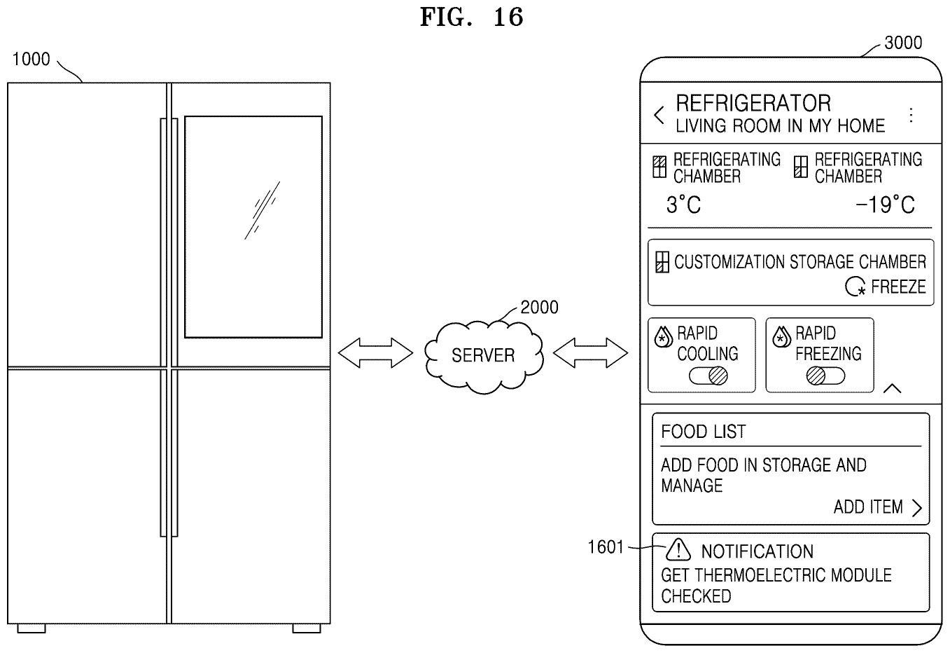

In addition, according to an embodiment of the disclosure, the refrigerator 1000 may allow a user terminal connected thereto via a server to output a notification message indicating that the thermoelectric module 210 requires checking. An operation of outputting the notification message informing that the thermoelectric module 210 of the refrigerator 1000 requires checking from the user terminal will be described later with reference to FIG. 16.

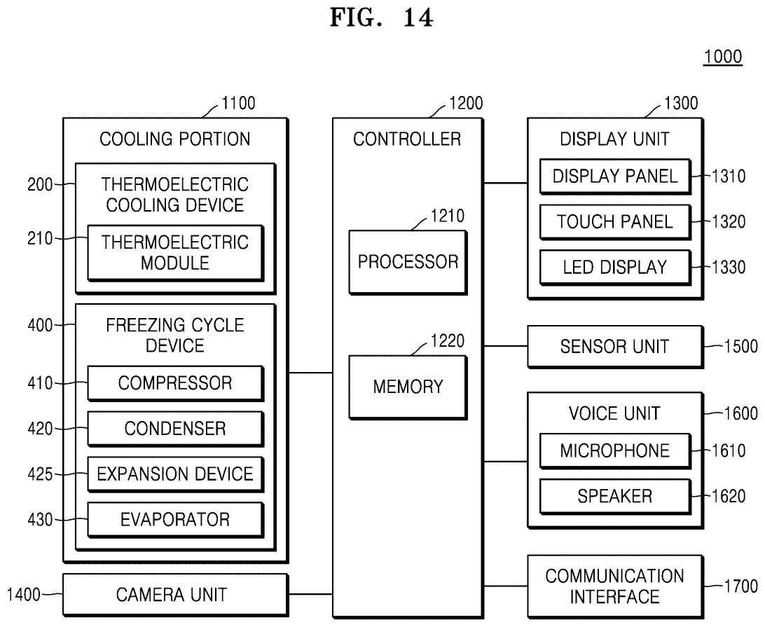

FIG. 14 is a block diagram for describing functional elements of the refrigerator 1000 according to an embodiment of the disclosure.

As shown in FIG. 14, the refrigerator 1000 according to an embodiment of the disclosure may include a cooling portion 1100, a controller 1200, a display unit 1300, a camera unit 1400, a sensor unit 1500, a voice unit 1600, and a communication interface 1700. However, at least one of the components shown in FIG. 14 may not be essential. The refrigerator 1000 may be embodied with more components than the components shown in FIG. 14 or may be embodied with fewer components than the components shown in FIG. 14.

Hereinafter, the components shown in FIG. 14 will be described in detail.

The cooling portion 1100 may include the thermoelectric cooling device 200 and the freezing cycle device 400. The thermoelectric cooling device 200 may include the thermoelectric module 210. The thermoelectric module 210 may have a thin hexahedral shape, and the heating portion 212 may be provided on one surface of the thermoelectric module 210 and the cooling portion 211 may be provided on the opposite surface, which is opposite to the one surface. The thermoelectric cooling device 200 is substantially the same as that described above with reference to FIGS. 2 and 3, and any repetitive detailed descriptions thereof will be omitted.

The freezing cycle device 400 may include a compressor 410, a condenser 420, an evaporation device 425, and an evaporator 430.

The compressor 410 compresses a refrigerant in high-temperature and high-pressure status. The compressor 410 may receive electrical energy from the outside and compress a gas-phase refrigerant with high-temperature and high-pressure by using a rotating force of an electrical motor, etc. The compressor 410 is connected to the condenser 420 and may move the compressed refrigerant to the condenser 420. The compressor 410 compresses the refrigerant and pushes the refrigerant to the condenser 420 and initiates a freezing cycle including compressing, condensing, expanding, and evaporating. Therefore, when the compressor 410 is driven, the cold air generated in the evaporator 430 is supplied to the storage chamber.

The condenser 420 condenses the refrigerant of high-pressure and high-temperature compressed by the compressor 410. The condenser 420 dissipates heat that is generated while condensing the refrigerant. The condensed refrigerant while passing through the condenser 420 is moved to the evaporation device 415 (expansion valve). The refrigerant condensed in the condenser 420 may become a liquid phase of low temperature and low pressure while passing through the evaporation device 425 (expansion valve). The refrigerant of liquid-phase passes through the evaporation device 425 (expansion valve) to the evaporator 430.

The evaporator 430 vaporizes the liquid-phase refrigerant of low-temperature and low-pressure that has passed through the expansion valve. In the evaporator 430, the liquid-phase refrigerant exchanges heat with peripheral gas while being vaporized. The liquid-phase refrigerant absorbs latent heat from the periphery, and accordingly, the gas around the evaporator 430 is cooled down and generates the cold air. The refrigerant that has completely vaporized is supplied into the compressor 410 again, and the cooling cycle circulates. A heater for removing frost from the evaporator 430 may be provided around the evaporator 430.

The controller 1200 may include a memory 1220 that stores programs and/or data for controlling the refrigerator 1000, and a processor 1210 configured to output a control signal for controlling the cooling portion 1100, etc. according to the programs and/or data stored in the memory 1220.

There may be one processor 1210 or a plurality of processors 1210 in the refrigerator 1000. The processor 1210 may include at least one selected from a central processing unit (CPU), a graphics processing unit (GPU), an accelerated processing unit (APU), a many integrated core (MIC), a digital signal processor (DSP), or a neural processing unit (NPU). The at least one processor 1210 may be implemented in an integrated system on chip (SoC) type including one or more electronic components. The at least one processor 1210 may be each implemented as separated hardware (H/W). The at least one processor 1210 may be expressed as a micro-computer, microprocessor computer, microprocessor controller (MICOM), a micro-processor unit (MPU), or a micro controller unit (MCU).

The at least one processor 1210 according to an embodiment of the disclosure may be implemented as a single core processor or a multi-core processor.

The memory 1220 may store or record various information, data, instructions, programs, etc. required to operate the refrigerator 1000. The memory 1220 may record temporary data generated while generating a control signal for controlling components included in the refrigerator 1000. The memory 1220 may include at least one selected from a volatile memory or a non-volatile memory, or a combination thereof.

The memory 1220 may include a storage medium of at least one type of a flash memory type, a hard disk type, a multimedia card micro type, a card type memory (e.g., an SD or XD memory, etc.), random access memory (RAM), static RAM (SRAM), read-only memory (ROM), electrically erasable programmable ROM (EEPROM), programmable (PROM), a magnetic memory, a magnetic disk, or an optical disk. The programs stored in the memory 1220 may be classified in a plurality of modules according to functions thereof.

The display unit 1300 is provided to output video signals. The display unit 1300 may include a display panel 1310 and a touch panel 1320. In an embodiment where the display panel 1310 and the touch panel 1320 are configured as a touch screen in a layered structure, the display unit 1300 may be used as an input device, in addition to as an output device.

The display unit 1300 may include at least one selected from a liquid crystal display unit, a thin film transistor-liquid crystal display unit, an organic light-emitting diode display unit, a flexible display unit, a three-dimensional (3D) display unit, or an electrophoretic display unit. In addition, the refrigerator 1000 may include two or more display units 1300 according to an implementation type of the refrigerator 1000.

According to an embodiment of the disclosure, the display unit 1300 may include a light-emitting diode (LED) display 1330. The LED display 1330 may blink in a certain color (e.g., red, blue, etc.) when the notification message is output as voice through the speaker 1620.

The camera unit 1400 may include an external camera configured to capture images of the external environment and/or an internal camera configured to capture images of internal environment. There may be a plurality of internal cameras configured to capture images of the internal environment. For example, the internal cameras may include a main camera located at the upper center portion of the refrigerator 1000 and sub-cameras located in the storage chambers. The camera unit 1400 may include at least one selected from an RGB camera, a depth camera, or a thermal imaging camera.

The sensor unit 1500 may include at least one selected from an environmental sensor, a proximity sensor, a door opening/closing sensor, or a polarization sensor, but is not limited thereto. The environmental sensor is a sensor for obtaining environmental information in the refrigerator 1000, and may include at least one selected from a smell sensor, a temperature sensor, or a humidity sensor. Because one of ordinary skill in the art would have understood functions of the sensors from the sensors' names, detailed descriptions thereof will be omitted.

The voice unit 1600 may include a microphone 1610 and a speaker 1620.

The microphone 1610 receives a sound signal from outside and processes the sound signal as electrical voice data. For example, the microphone 1610 may receive a sound signal (e.g., voice command) from an external device or a narrator. The microphone 1610 may use various noise cancelling algorithms for cancelling noise occurring when receiving the sound signal from the outside.

The speaker 1620 outputs audio data received from the communication interface 1700 or stored in the memory 1220. Also, the speaker 1620 outputs a sound signal related to functions (e.g., message receiving sound and notification sound) executed in the refrigerator 1000.

The communication interface 1700 may include a short-range wireless communication interface, a long-range communication interface, etc. The short-range wireless communication interface may include, but is not limited to, a Bluetooth communicator, a Bluetooth low energy (BLE) communicator, a near field communication interface (NFC), a WLAN (Wi-Fi) communicator, a ZigBee communicator, an infrared-ray data association (IrDA) communicator, a Wi-Fi direct (WFD) communicator, an ultra-wideband (UWB) communicator, an Ant+ communicator, etc. The long-range communication interface may be used when the refrigerator 1000 remotely communicates with the server 2000. The long-range communication interface may include Internet, computer network (e.g., LAN or WAN), or a mobile communicator. The mobile communicator may include a 3G module, a 4G module, a 5G module, a long-term evolution (LTE) communication module, an NB-IoT module, an LTE-M module, etc., but is not limited thereto.

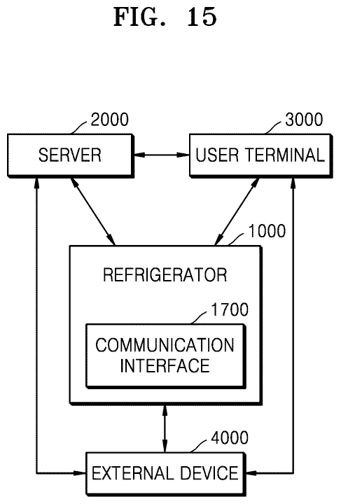

FIG. 15 is a diagram for describing a communication system in the refrigerator 1000 according to an embodiment of the disclosure.

The refrigerator 1000 according to an embodiment of the disclosure may communicate with the server 2000, a user terminal 3000, and an external device 4000 via a network.

The server 2000 may include a communication module configured to communicate with another server, the refrigerator 1000, the external device 4000, or the user terminal 3000, at least one processor configured to process data received from another server, the refrigerator 1000, the external device 4000, or the user terminal 3000, and at least one memory that stores programs for processing data or processed data. The server 2000 may be implemented as various computing devices such as a workstation, a cloud, a data drive, a data station, etc. The server 2000 may be implemented as one or more servers that are physically or logically divided based on functions, detailed configurations of functions, or data, and may transmit and receive data through communication between each server and process the transmitted and received data.

The server 2000 may perform functions, such as of managing a user account, registering the refrigerator 1000 and the external device 4000 to be associated with the user account, and managing or controlling the registered refrigerator 1000 and the external device 4000. For example, a user may access the server 2000 through the user terminal 3000 and generate a user account. A user account may be identified by an identifier (ID) and a password set by the user. The server 2000 may register the refrigerator 1000 and the external device 4000 on a user account according to a predetermined procedure. For example, the server 2000 may register, manage, and control the refrigerator 1000 and the external device 4000 by connecting identification information (e.g., a serial number or a media access control (MAC) address) of the refrigerator 1000 and the external device 4000 to a user account.

The user terminal 3000 may include a communication module for communicating with the refrigerator 1000, the external device 4000, or the server 2000, a user interface for receiving a user input or outputting information to the user, at least one processor for controlling the operation of the user terminal 3000, and at least one memory in which a program for controlling the operation of the user terminal 3000 is stored.

The user terminal 3000 may be carried by the user or placed in the user's home or office. The user terminal 3000 may include a personal computer, a terminal, a portable telephone, a smart phone, a handheld device, a wearable device, and the like, but is not limited thereto.

A program for controlling the refrigerator 1000 and the external device 4000, that is, an application, may be stored in the memory of the user terminal 3000. The application may be sold in a state of being installed on the user terminal 3000 or may be downloaded from an external server and installed.

The user may execute an application installed on the user terminal 3000 to access the server 2000 and generate a user account, and may perform communication with the server 2000 based on the logged-in user account to register the refrigerator 1000 and the external device 4000.

For example, when the user manipulates the refrigerator 1000 and the external device 4000 such that the refrigerator 1000 and the external device are connected to the server 2000 according to a procedure guided by an application installed in the user terminal 3000, the server 2000 may include identification information (e.g., a serial number or a MAC address) of the refrigerator 1000 and the external device 4000 in a corresponding user account, such that the refrigerator 1000 and the external device 4000 may be registered on the user account.

The user may control the refrigerator 1000 and the external device 4000 using an application installed on the user terminal 3000. For example, when a user logs in to a user account with the application installed on the user terminal 3000, the refrigerator 1000 and the external device 4000 registered on the user account are displayed, and when the user inputs a control command for the refrigerator 1000 or the external device 4000, the control command may be transmitted to the refrigerator 1000 or the external device 4000 through the server 2000.

The external device 4000 may include a communication module configured to communicate with the refrigerator 1000, the user terminal 3000, or the server 2000, a user interface for receiving a user input or outputting information to the user, at least one processor configured to control operations of the external device 4000, and at least one memory that stores a program for controlling the operations of the external device 4000.

The external device 4000 may be at least one selected from various kinds of home appliances. For example, the external device 400 may include, but is not limited to, at least one selected from a dishwasher, an electric stove, an electric oven, an air conditioner, a clothing care machine, a washing machine, a dryer, a microwave oven, an air purifier, a robot cleaner, a vacuum cleaner, or a television.

A network may include both a wired network and a wireless network. The wired network may include a cable network or a telephone network, and the wireless network may include any network that transmits and receives signals through radio waves. A wired network and a wireless network may be connected to each other.

The network may include a wide area network (WAN), such as the Internet, a local area network (LAN) formed around an access point (AP), and/or a short-range wireless network not using an AP. Short-range wireless networks may include, for example, Bluetooth™ (IEEE 802.15.1), Zigbee (IEEE 802.15.4), Wi-Fi Direct, near field communication (NFC), Z-Wave and the like, but are not limited thereto.

The AP may connect the refrigerator 1000, the external device 4000, or the user terminal 3000 to a WAN to which the server 2000 is connected. The refrigerator 1000, the external device 4000, or the user terminal 3000 may be connected to the server 2000 via a WAN.

The AP may use wireless communication, such as Wi-Fi™ (IEEE 802.11), Bluetooth (IEEE 802.15.1), Zigbee (IEEE 802.15.4), etc. to communicate with the user device 2 or the user device 2, and may use wired communication to access a WAN, but is not limited thereto.

According to an embodiment of the disclosure, the refrigerator 1000 may be directly connected to the user terminal 3000, the external device or the server 2000 without using an AP.

The refrigerator 1000 may be connected to the external device 4000, the user terminal 3000, or the server 2000 through a long-range wireless network or a short-range wireless network. For example, the refrigerator 1000 may be connected to the user terminal 3000 through a short-range wireless network (e.g., Wi-Fi Direct).

The refrigerator 1000 may be connected to the user terminal 3000, the server 2000, or the external device 4000 through a WAN using a long-range wireless network (e.g., a cellular communication module). Also, the refrigerator 1000 may access a WAN using wired communication, and connect to the user terminal 3000, the server 2000, or the external device 4000 through the WAN.

When the refrigerator 1000 is allowed to access a WAN using wired communication, the refrigerator 1000 may operate as an AP. Accordingly, the refrigerator 1000 may connect the external device 4000 to the WAN to which the server 2000 is connected. In addition, the external device 4000 may connect the refrigerator 1000 to the WAN to which the server 2000 is connected.

The refrigerator 1000 may transmit information about an operation or state to the external device 4000, the user terminal 3000, or the server 2000 through a network. For example, when a request is received from the server 2000, or when a specific event occurs in the refrigerator 1000, or periodically or in real time, the refrigerator 1000 may transmit information about the operation or state to the external device 4000, the user terminal 3000, and the server 2000. The server 2000 may, upon receiving the information about the operation or state of the refrigerator 1000, update stored information about an operation or state of the refrigerator 1000, and transmit the updated information about the operation and state of the refrigerator 1000 to the user terminal 3000 through the network. Here, updating information may include various operations of changing existing information, such as adding new information to existing information or replacing existing information with new information.

The refrigerator 1000 may acquire various types of information from the external device 4000, the user terminal 3000, or the server 2000 and provide the acquired information to the user. For example, the refrigerator 1000 may receive information (e.g., recipes, etc.), related to functions of the refrigerator 1000 from the server 2000 and various types of environmental information (e.g., a weather, a temperature, a humidity, etc.), and may output the acquired information through a user interface.

The refrigerator 1000 may operate based on a control command received from the external device 4000, the user terminal 3000, or the server 2000. For example, the refrigerator 1000 may, even without a user input, upon acquiring a user's prior approval to operate according to a control command of the server 2000, operate according to a control command received from the server 2000. Here, the control command received from the server 2000 may include a control command input by a user through the user terminal 3000 or a control command based on a preset condition, but is not limited thereto.

The user terminal 3000 may transmit information about the user to the refrigerator 1000, the external device 4000, or the server 2000 through the communication module. For example, the user terminal 3000 may transmit information about the user's location, the user's health condition, the user's taste, and the user's schedule to the server 2000. The user terminal 3000 may transmit the information about the user to the refrigerator 1000 or the server 2000 according to a user's prior approval.

The refrigerator 1000, the external device 4000, the user terminal 3000, or the server 2000 may determine a control command using artificial intelligence and other technologies. For example, the server 2000 may receive information about the operation or state of the refrigerator 1000 and the external device 4000 or receive information about the user of the user terminal 3000, and process the received information using technology such as artificial intelligence, and then transmit a processing result or a control command to the refrigerator 1000, the external device 4000, or the user terminal 3000.

Hereinafter, operations of the refrigerator 1000 for linking with the user terminal 3000 via the server 2000 will be described with reference to FIG. 16.

FIG. 16 is a diagram for illustrating operations of the refrigerator 1000 for linking with the user terminal 3000, according to an embodiment of the disclosure.

Referring to FIG. 16, in an embodiment, when sensing that at least one of the plurality of groups of the internal elements included in the thermoelectric module 210 has lost a function, the refrigerator 1000 may transmit to the server 2000 information that the thermoelectric module 210 requires checking. The server 2000 may be a server for managing home appliances such as the refrigerator 1000. For example, when one of the two groups included in the thermoelectric module 210 has lost a function, the refrigerator 1000 may transmit to the server the information indicating that the thermoelectric module 210 requires checking through the communication interface 1700.

The server 2000 may transfer the information indicating that the thermoelectric module 210 requires checking to the user terminal 3000 that is registered in the same user account as that of the refrigerator 1000. Here, the user terminal 3000 may output a notification message 1601 indicating that the thermoelectric module 210 requires checking through an application execution window. The user may identify the notification message 1601 indicating the checking of the thermoelectric module 210, and may get some check-up on the thermoelectric module 210 of the refrigerator 1000.

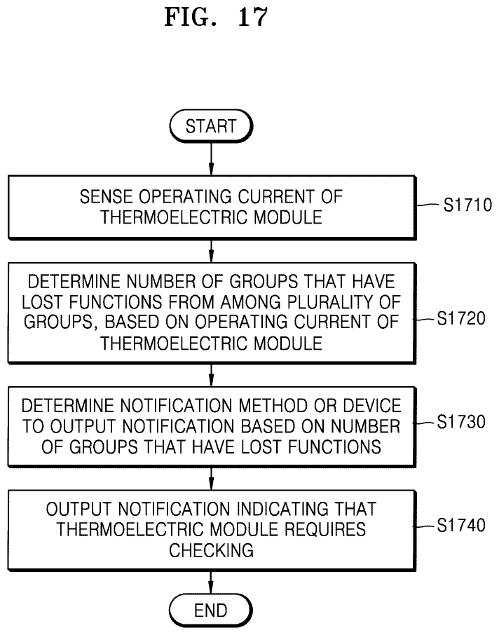

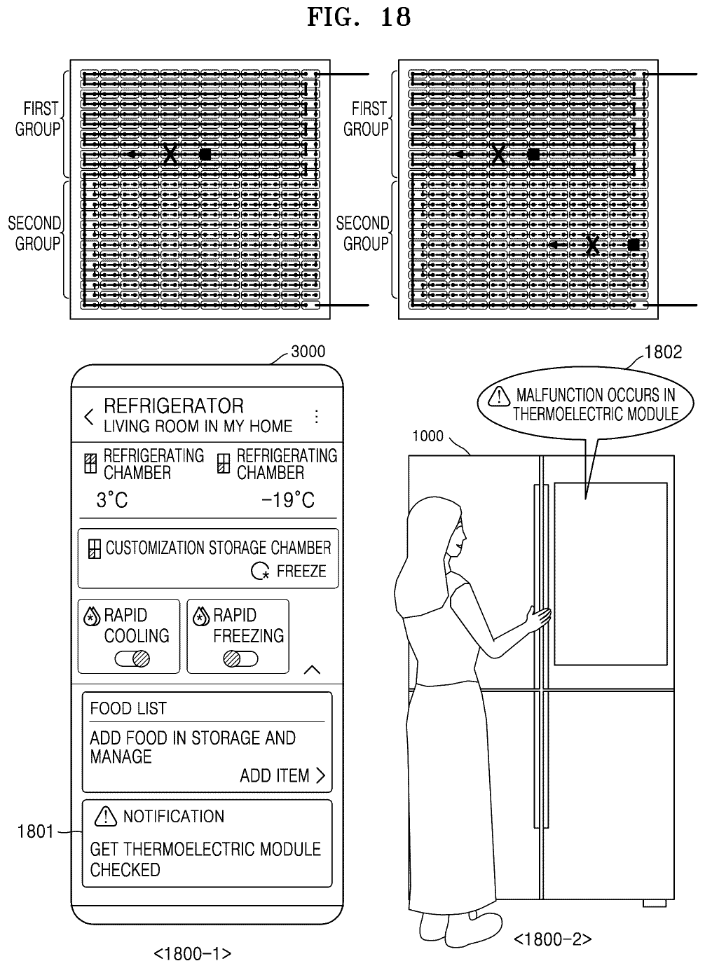

In addition, according to an embodiment of the disclosure, the refrigerator 1000 may apply the notification type differently depending on the number of groups determined as having lost the functions, from among the plurality of groups included in the thermoelectric module 210. Hereinafter, referring to FIGS. 17 and 18, an operation of the refrigerator 1000 for outputting notification messages in different ways is described below.

FIG. 17 is a flowchart of a method, performed by the refrigerator 1000, of determining a notification type or a device to output a notification according to the number of groups that lost the functions, from among a plurality of groups, according to an embodiment of the disclosure.

Referring to FIG. 17, an embodiment of the method for the refrigerator 1000 to determine the notification type or device to output the notification may include operation S1710 to operation S1740. In an embodiment of the disclosure, operation S1710 to operation S1740 may be executed by at least one processor included in the refrigerator 1000. Embodiments of the method, by which the refrigerator 1000 determines the notification type or device to output the notification, are not limited to the method shown in FIG. 17, and in one or more embodiments of the disclosure, the method may further include a process not shown in FIG. 17 or some of the operations shown in FIG. 17 may be omitted.

In operation S1710, the refrigerator 1000 according to an embodiment of the disclosure may sense the operating current of the thermoelectric module 210 via the current sensing circuit 1102, when the thermoelectric module 210 operates.

In operation S1720, the refrigerator 1000 according to an embodiment of the disclosure may determine the number of groups have lost the functions, from among the plurality of groups, based on the operating current of the thermoelectric module 210.

According to an embodiment of the disclosure, where the thermoelectric module 210 includes the first group and the second group and one P or N-type element included in the first group is damaged, the electric current may not further flow to the first group. Therefore, the total resistance of the thermoelectric module 210 may be reduced to half, and the operating current of the thermoelectric module 210 may be increased by twice. Here, the refrigerator 1000 senses that the operating current of the thermoelectric module 210 increases twice, and may identify that one of the two groups has lost a function. According to an embodiment of the disclosure, when the operating current of the thermoelectric module 210 is zero (0) A, the refrigerator 1000 may identify that all of the groups included in the thermoelectric module 210 have lost the functions. That is, according to an embodiment of the disclosure, when the operating current of the thermoelectric module 210 increases twice, the refrigerator 1000 determines that the number of groups having lost the functions is one, and when the operating current of the thermoelectric module 210 is zero (0) A, the refrigerator 1000 may determine that the number of groups having lost the functions may be two.

In an embodiment, where the thermoelectric module 210 includes the first group, the second group, and the third group, and one P or N-type element included in the second group is damaged, the electric current may not further flow in the second group. Therefore, the total resistance of the thermoelectric module 210 may be reduced by about 30%, and the operating current of the thermoelectric module 210 may be increased by about 30%. The refrigerator 1000 may sense that the operating current of the thermoelectric module 210 increases, and identify that one of the three groups has lost a function. Also, when one element included in the first group and one element included in the second group are damaged, the total resistance of the thermoelectric module 210 may be reduced by about 60% and the operating current may be increased by about 60%. The refrigerator 1000 may sense that the operating current of the thermoelectric module 210 rapidly increases, and may identify that two of the three groups have lost the functions. Also, when the operating current of the thermoelectric module 210 is zero (0) A, the refrigerator 1000 may identify that all of the three groups have lost the functions.

In operation S1730, the refrigerator 1000 according to an embodiment of the disclosure may determine the notification type or the device to output the notification according to the number of groups having lost the functions.

According to an embodiment of the disclosure, when some of the plurality of groups included in the thermoelectric module 210 have lost the functions, the refrigerator 1000 determines that the notification is output through the user terminal 3000, and when all of the plurality of groups have lost the functions, the refrigerator 1000 may determine that the notification is output through the display unit 1300 of the refrigerator 1000 or the speaker 1620 of the refrigerator 1000.

In such embodiments, for example, even when some of the plurality of groups in the thermoelectric module 210 have lost the functions, entire function of the thermoelectric module 210 is lost. Thus, there is no need to notify the user in a rush. On the other hand, when all of the plurality of groups included in the thermoelectric module 210 have lost the functions, there is a concern about the cooling function of the storage chamber may have an issue, and thus, the user has to be notified rapidly. Therefore, the refrigerator 1000 may select the user terminal 3000 as a device to output a notification when some groups have lost the functions, and may select the refrigerator 1000 as a device to output the notification when all of the plurality of groups have lost the functions.

In addition, according to an embodiment of the disclosure, the refrigerator 1000 may select the method of outputting the notification through the display unit 1300 when some of the plurality of groups included in the thermoelectric module 210 have lost the functions, and may select the method of outputting the notification through the speaker 1620 when all of the plurality of groups have lost the functions. Alternatively, the refrigerator 1000 may select the method of visually displaying the notification message via the display unit 1300 or the user terminal 3000 when some of the plurality of groups included in the thermoelectric module 210 have lost the functions, and may select the method of visually displaying the notification message on the display unit 1300, and at the same time, audibly outputting the notification message via the speaker 1620 when all of the plurality of groups have lost the functions. The notification type is not limited to the above examples, but may be variously selected.

In operation S1740, the refrigerator 1000 according to an embodiment of the disclosure may output a notification indicating that the thermoelectric module 210 requires checking based on the notification type or device determined in operation S1730. Examples in which the refrigerator 1000 outputs the notification indicating that the thermoelectric module 210 requires checking are described below with reference to FIG. 18.

FIG. 18 is a diagram for describing an operation of the refrigerator 1000 to determine a notification type or a device to output a notification according to the number of groups that lost the functions, according to an embodiment of the disclosure. In FIG. 18, an embodiment in which the internal elements of the thermoelectric module 210 are divided into the first group and the second group is shown as an example.

Referring to 1800-1 in FIG. 18, in an embodiment, the refrigerator 1000 senses the variation in the operating current of the thermoelectric module 210, and may identify that one (e.g., first group) of the plurality of groups in the thermoelectric module 210 has lost a function. When one of the plurality of groups in the thermoelectric module 210 has lost a function, the refrigerator 1000 may determine that a notification is to be output through the user terminal 3000. The refrigerator 1000 may transfer the information indicating that the thermoelectric module 210 requires checking to the server 2000. The server 2000 may transfer to the user terminal 3000 registered to the same account as the refrigerator 1000 a command for outputting the notification indicating that the thermoelectric module 210 requires checking. The user terminal 3000 may output a notification 1801 to the user, indicating that the thermoelectric module 210 of the refrigerator 1000 requires checking, via a certain application (e.g., a home appliance management application) according to the command from the server 2000. The user may execute the certain application on the user terminal 3000 and may identify the notification indicating that the thermoelectric module 210 requires checking.

Referring to 1800-2 of FIG. 18, in an embodiment, when the operating current of the thermoelectric module 210 is 0 A, the refrigerator 1000 may identify that all of the plurality of groups included in the thermoelectric module 210 have lost the functions. When all of the plurality of groups included in the thermoelectric module 210 have lost the functions, there may be an issue in the cooling function of the storage chamber, and thus, the refrigerator 1000 may determine that the notification is to be output through the speaker 1620 of the refrigerator 1000, indicating that the thermoelectric module 210 requires checking. Therefore, the refrigerator 1000 may sense the user approaching the refrigerator 1000 via a human sensor, and may output a voice message 1802 indicating that there is an error occurring in the thermoelectric module 210 to the user. In this case, the user may identify the voice message 1802 output through the speaker 1602 in real-time, and may get some check-up on the thermoelectric module 210 within a short period of time.

According to an embodiment of the disclosure, the refrigerator 1000 including the thermoelectric module 210 (Peltier module) on an upper end of the main body 100 may be provided. In such an embodiment, the thermoelectric module 210 include internal elements that are divided into a plurality of groups which are connected to a power line connected to the thermoelectric module 210 in parallel with each other, and thus, loss of the performance of the entire thermoelectric module due to one defective internal element may be effectively prevented.

According to an embodiment of the disclosure, the refrigerator 1000 may include the main body 100 including at least one storage chamber, doors 11, 12, 13, and 14 provided to open or close the at least one storage chamber, the thermoelectric module 210 configured to cool down the at least one storage chamber, and the at least one processor 1210 configured to control the thermoelectric module 210. The internal elements in the thermoelectric module 210 may be classified into a plurality of groups, and the internal elements in each of the plurality of groups are connected to each other in series. The plurality of groups may be connected in parallel with each other between a positive (+) power line and a negative (−) power line connected to opposite ends of the thermoelectric module 210. Therefore, according to an embodiment of the disclosure, even when an open defect occurs in one element included in the thermoelectric module 210, the thermoelectric module 210 may maintain 50% of the functions thereof or greater.

According to an embodiment of the disclosure, a start point of an arrangement of the internal elements in each of the plurality of groups may be connected to the positive (+) power line and an end point of the arrangement of the internal elements in each of the plurality of groups may be connected to the negative (−) power line.

The plurality of groups according to an embodiment of the disclosure may be commonly connected the positive (+) power line and the negative (−) power line.

According to an embodiment of the disclosure, the internal elements included in different groups may be electrically disconnected from each other except for an input node thereof and an output node thereof.

The plurality of groups according to an embodiment of the disclosure may include a first group and a second group. The first internal elements included in the first group and the second internal elements included in the second group may be arranged to be distributed entirely throughout the thermoelectric module 210.

In the thermoelectric module 210 according to an embodiment of the disclosure, the heating portion 211 faces the upper portion of the thermoelectric module 210 and the cooling portion 212 may be arranged on the upper end of the main body 100 to face the lower portion of the thermoelectric module 210.

The refrigerator 1000 according to an embodiment of the disclosure may include the voltage sensing circuit 1101 configured to sense the voltage input to the thermoelectric module 210 and the current sensing circuit 1102 configured to sense the operating current of the thermoelectric module 210.

The at least one processor according to an embodiment of the disclosure may identify the loss of function in at least one of the plurality of groups included in the thermoelectric module 210 based on the variation in the operating current of the thermoelectric module 210 sensed through the current sensing circuit 1102.

The at least one processor according to an embodiment of the disclosure may determine, when identifying the loss of function in at least one group, whether current power consumption of one group exceeds maximum power consumption of the one group.

The at least one processor according to an embodiment of the disclosure may reduce a magnitude of the voltage input to the thermoelectric module 210 when the current power consumption of the one group exceeds the maximum power consumption of the one group.

The at least one processor according to an embodiment of the disclosure may maintain the magnitude of the voltage input to the thermoelectric module 210 to remain consistent, when the current power consumption of one group is less than or equal to the maximum power consumption of the one group.

The at least one processor according to an embodiment of the disclosure may output, through the display unit 1300 of the refrigerator 1000 or the speaker 1620 of the refrigerator 1000, a notification indicating that the thermoelectric module requires checking when the loss of function in at least one group is identified.

The at least one processor according to an embodiment of the disclosure may transmit to the server 2000 the information indicating that the thermoelectric module 210 requires checking, in response to the identification of the loss of function in at least one group.

The at least one processor according to an embodiment of the disclosure may determine the number of groups identified as having lost the function, from among the plurality of groups, based on the operating current of the thermoelectric module 210.

The at least one processor according to an embodiment of the disclosure may determine a notification method or the device to output the notification based on the number of groups identified as having lost the function from among the plurality of groups.

The at least one processor according to an embodiment of the disclosure may output, through the user terminal 3000 connected via the server 2000, a notification indicating that the thermoelectric module 210 requires checking when it is determined that some of the plurality of groups have lost functions thereof. The at least one processor according to an embodiment of the disclosure may output, through the display unit 1300 of the refrigerator 1000 or the speaker 1620 of the refrigerator 1000, a notification indicating that the thermoelectric module 210 requires checking when it is determined that all of the plurality of groups have lost functions thereof.

According to an embodiment of the disclosure, the voltage sensing circuit 1101 and the current sensing circuit 1102 may be arranged on the printed circuit board of a power supply device which supplies power to the thermoelectric module 210.

The refrigerator 1000 according to an embodiment of the disclosure may further include the freezing cycle device 400 including the compressor 410, the condenser 420, the expansion device 425, and the evaporator 430.

The at least one processor according to an embodiment of the disclosure may selectively operate at least one selected from the freezing cycle device 400 or the thermoelectric cooling device 200 including the thermoelectric module 210, based on the operating environment of the refrigerator 1000.

According to an embodiment of the disclosure, a method, performed by the refrigerator 1000, of controlling the thermoelectric module 210 includes: sensing an operating current of the thermoelectric module by using a current sensing circuit, where the thermoelectric module includes internal elements classified into a plurality of groups, and the internal elements in each of the plurality of groups are connected to each other in series, and the plurality of groups are connected in parallel with each other to a power line connected to the thermoelectric module (S1010); identifying a loss of function in at least one of the plurality of groups included in the thermoelectric module, based on a variation in the operating current of the thermoelectric module (S1020); determining whether current power consumption of one group exceeds maximum power consumption of the one group, when identifying the loss of function in at least one group (S1030); and reducing a magnitude of the voltage input to the thermoelectric module when the current power consumption of the one group exceeds the maximum power consumption of the one group (S1040).

The method of controlling the thermoelectric module 210 by the refrigerator 1000 according to an embodiment of the disclosure, may include maintaining constant the magnitude of the voltage input to the thermoelectric module when it is determined that the current power consumption of the one group is less than or equal to the maximum power consumption of the one group (S1050).

The method of controlling the thermoelectric module 210 by the refrigerator 1000 according to an embodiment of the disclosure, may include outputting, through a display unit 1300 of the refrigerator or a speaker 1620 of the refrigerator, a notification indicating that the thermoelectric module requires checking when the loss of function in at least one group is identified (S1250).

The method of controlling the thermoelectric module 210 by the refrigerator 1000 according to the embodiment of the disclosure, may include transmitting to a server 2000 information indicating that the thermoelectric module requires checking, when the loss of function in at least one group is identified.

The machine-readable storage medium may be provided in the form of a non-transitory storage medium. Here, the term ‘non-transitory’ simply means that the storage medium is a tangible device, and does not include a signal (e.g., an electromagnetic wave), but this term does not differentiate between where data is semi-permanently stored in the storage medium and where the data is temporarily stored in the storage medium. For example, the ‘non-transitory storage medium’ may include a buffer in which data is temporarily stored.

According to an embodiment of the disclosure, the method according to various embodiments disclosed herein may be provided to be included in a computer program product. The computer program product may be traded between a seller and a buyer as a product. The computer program product may be distributed in the form of a machine-readable storage medium (e.g., compact disc read only memory (CD-ROM) or universal serial bus (USB) flash drive), or may be distributed through an application store online (e.g., download or upload) or directly between two user devices (e.g., smartphones). When distributed online, at least part of the computer program product (e.g., downloadable app) may be temporarily generated or at least temporarily stored in the machine-readable storage medium, such as memory of the manufacturer's server, a server of the application store, or a relay server.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A refrigerator comprising:
a main body including at least one storage chamber;
doors provided to open or close the at least one storage chamber;
a thermoelectric module configured to cool down the at least one storage chamber; and
at least one processor configured to control the thermoelectric module,
wherein the thermoelectric module includes internal elements classified into a plurality of groups,
wherein the internal elements in each of the plurality of groups are connected to each other in series, and
wherein the plurality of groups are connected in parallel with each other to a power line connected to the thermoelectric module.

2. The refrigerator of claim 1, wherein a start point of an arrangement of the internal elements in each of the plurality of groups is connected to a positive (+) power line and an end point of the arrangement of the internal elements in each of the plurality of groups is connected to a negative (−) power line.

3. The refrigerator of claim 2, wherein the plurality of groups are commonly connected to the positive (+) power line and the negative (−) power line.

4. The refrigerator of claim 1, wherein the internal elements in different groups are electrically disconnected from each other except for an input node and an output node thereof.

5. The refrigerator of claim 1, wherein the plurality of groups include a first group and a second group, and
first internal elements included in the first group and second internal elements included in the second group are arranged to be distributed entirely throughout the thermoelectric module.

6. The refrigerator of claim 1, wherein the thermoelectric module is arranged on an upper end of the main body such that a heating portion faces an outside of the refrigerator and a cooling portion faces an inside of the refrigerator.

7. The refrigerator of claim 1, further comprising:
a voltage sensing circuit configured to sense a voltage input to the thermoelectric module; and
a current sensing circuit configured to sense an operating current of the thermoelectric module.

8. The refrigerator of claim 7, wherein at least one processor is further configured to identify a loss of function in at least one of the plurality of groups included in the thermoelectric module, based on a variation in an operating current of the thermoelectric module sensed by the current sensing circuit.

9. The refrigerator of claim 8, wherein at least one processor is further configured to determine, when identifying the loss of function in the at least one group, whether current power consumption of one group exceeds maximum power consumption of the one group.

10. The refrigerator of claim 9, wherein at least one processor is further configured to reduce a magnitude of the voltage input to the thermoelectric module when the current power consumption of the one group exceeds the maximum power consumption of the one group.

11. The refrigerator of claim 9, wherein at least one processor is further configured to maintain a magnitude of the voltage input to the thermoelectric module to remain consistent, when the current power consumption of the one group is less than or equal to the maximum power consumption of the one group.

12. The refrigerator of claim 8, wherein at least one processor is further configured to output, through a display unit of the refrigerator or a speaker of the refrigerator, a notification indicating that the thermoelectric module requires checking when the loss of function in the at least one group is identified.

13. The refrigerator of claim 8, wherein at least one processor is further configured to transmit to a server information indicating that the thermoelectric module requires checking, when the loss of function in the at least one group is identified.

14. The refrigerator of claim 8, wherein at least one processor is further configured to
determine a number of groups identified as having lost functions thereof, from among the plurality of groups, based on the operating current of the thermoelectric module, and
determine a notification type or a device to output the notification, based on the number of the groups identified as having lost the functions thereof, from among the plurality of groups.

15. The refrigerator of claim 14, wherein at least one processor is further configured to
output, through a user terminal connected via a server, a notification indicating that the thermoelectric module requires checking when it is determined that some of the plurality of groups have lost functions thereof, and
output, through a display unit of the refrigerator or a speaker of the refrigerator, the notification indicating that the thermoelectric module requires checking when it is determined that all of the plurality of groups have lost functions thereof.

16. The refrigerator of claim 1, wherein at least one processor is further configured to selectively operate at least one selected from a freezing cycle device or a thermoelectric cooling device including the thermoelectric module based on an operating environment of the refrigerator.

17. A method of controlling, performed by a refrigerator, a thermoelectric module, the method comprising:
sensing an operating current of the thermoelectric module by using a current sensing circuit, wherein the thermoelectric module includes internal elements classified into a plurality of groups, the internal elements in each of the plurality of groups are connected to each other in series, and the plurality of groups are connected in parallel with each other to a power line connected to the thermoelectric module;
identifying a loss of function in at least one of the plurality of groups in the thermoelectric module, based on a variation in the operating current of the thermoelectric module;
determining whether current power consumption of one group exceeds maximum power consumption of the one group, when identifying the loss of function in the at least one group; and
reducing a magnitude of a voltage input to the thermoelectric module when the current power consumption of the one group exceeds the maximum power consumption of the one group.

18. The method of claim 17, further comprising maintaining constant the magnitude of the voltage input to the thermoelectric module when it is determined that the current power consumption of the one group is less than or equal to the maximum power consumption of the one group.

19. The method of claim 17, further comprising outputting, through a display unit of the refrigerator or a speaker of the refrigerator, a notification indicating that the thermoelectric module requires checking when the loss of function in the at least one group is identified.

20. The method of claim 17, further comprising transmitting, to a server, information indicating that the thermoelectric module requires checking, when the loss of function in the at least one group is identified.
